(19) United States
(12) Patent Application Publication
(10) Pub. No.: US 2017/0355591 A1
(43) Pub. Date: Dec. 14, 2017

(54) MICROELECTROMECHANICAL DEVICE AND A METHOD OF MANUFACTURING A MICROELECTROMECHANICAL DEVICE

(71) Applicant: Infineon Technologies AG, Neubiberg (DE)

(72) Inventors: Ursula Hedenig, Villach (AT); Markus Bergmeister, Villach (AT); Thomas Grille, Villach (AT)

(21) Appl. No.: 15/176,235

(22) Filed: Jun. 8, 2016

(51) Int. Cl. B81B 3/00; B81C 1/00

(52) U.S. Cl. CPC B81B 3/0021; B81C 1/00158; B81C 2201/013; B81B 2201/0257; B81B 2203/0127

(57) ABSTRACT

A method of manufacturing a microelectromechanical component, the method may include: forming a mask over a layer, the mask comprising a structured surface; heating a region of the mask comprising the structured surface above a glass transition temperature of the mask to smooth out edges of the structured surface to form a corrugated surface; etching the layer covered by the mask, the etching removing the mask to carry over the corrugated surface of the mask into the layer and to form a corrugated surface of the layer; forming a diaphragm over the layer to form a corrugated region of the diaphragm configured to actuate; and forming an electrically-conductive component configured to at least one of: provide a force to actuate the diaphragm in response to an electrical signal transmitted to the electrically-conductive component and provide an electrical signal in response to an actuation of the diaphragm.

### TECHNICAL FIELD

Various embodiments relate generally to a microelectromechanical component and a method of manufacturing a microelectromechanical component.

### BACKGROUND

Microelectromechanical systems (MEMS) may include a diaphragm and two electrodes, e.g., a dual backplate microphone (DBP microphone). MEMS may also be known as micromachines or micro systems technology. Such systems may include a corrugated diaphragm. A diaphragm that is corrugated may have an increased flexibility (or sensitivity or compliance), that increases a functional bandwidth of the diaphragm in, for example, a MEMS DBP microphone.

A DBP microphone may, for example, include an electrode on either side of the diaphragm. This arrangement may present difficulties in the manufacture of such a device due to factors such as device or material temperature budget or device scale. Therefore, a microelectromechanical device including a corrugated diaphragm and at least one electrode, as well as, a method of manufacturing such a microelectromechanical device, may be advantageous.

### BRIEF DESCRIPTION OF THE DRAWINGS

In the drawings, like reference characters generally refer to the same parts throughout the different views, e.g., layer 210, layer 310, layer 410, layer 510). The drawings are not necessarily to scale, emphasis instead generally being placed upon illustrating the principles of the invention. In the following description, various embodiments of the invention are described with reference to the following drawings, in which:

FIG. 1A-1B show rounding of photoresist.

FIG. 1C shows a method of manufacturing a microelectromechanical component.

FIG. 2A-2D show, in a partial view of a cross-section, a method of manufacturing a microelectromechanical component and the components at various stages of manufacture according to an embodiment of the disclosure.

FIG. 3A-3D show, in cross-section, a method of manufacturing a microelectromechanical component and the components at various stages of manufacture according to an embodiment of the disclosure.

FIG. 3E-3F show, in cross-section and projection, a method of manufacturing a microelectromechanical component and the components at various stages of manufacture according to an embodiment of the disclosure.

FIG. 4A-4U show, in cross-section, a method of manufacturing a microelectromechanical component and the components at various stages of manufacture according to an embodiment of the disclosure.

FIG. 5A-5E show, in cross-section, a method of manufacturing a microelectromechanical component and the components at various stages of manufacture according to an embodiment of the disclosure.

FIG. 5F shows a method of manufacturing a microelectromechanical component.

### DESCRIPTION

The following detailed description refers to the accompanying drawings that show, by way of illustration, specific details and embodiments in which the invention may be practiced. In the following figures, similar or the same elements may have similar or the same reference numerals (e.g., layer 210, layer 310, layer 410, layer 510). A description of the element may, in the interests of brevity and repetition prevention, therefore, be omitted in subsequent descriptions.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g., in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

As used herein, a “circuit” may be understood as any kind of logic (analog or digital) implementing entity, which may be special purpose circuitry or a processor executing software stored in a memory, firmware, hardware, or any combination thereof. Furthermore, a “circuit” may be a hard-wired logic circuit or a programmable logic circuit such as a programmable processor, for example a microprocessor (for example a Complex Instruction Set Computer (CISC) processor or a Reduced Instruction Set Computer (RISC) processor). A “circuit” may also be a processor executing software, for example, any kind of computer program, for example a computer program using a virtual machine code such as, for example, Java. Any other kind of implementation of the respective functions which will be described in more detail below may also be understood as a “circuit”. It is understood that any two (or more) of the described circuits may be combined into a single circuit with substantially equivalent functionality, and, conversely, that any single described circuit may be distributed into two (or more) separate circuits with substantially equivalent functionality. In particular with respect to the use of “circuitry” in the Claims included herein, the use of “circuit” may be understood as collectively referring to two or more circuits.

The term “forming” may refer to disposing, arranging, structuring, or depositing. A method for forming, e.g., a layer, a material, or a region, etc., may include various deposition methods which, inter alia, may include: chemical vapor deposition, physical vapor deposition (e.g., for dielectric materials), electrodeposition (which may also be referred to as electroplating, e.g., for metals or metal alloys), or spin coating (e.g., for fluid materials). Generally, a vapor deposition may be performed by sputtering, laser ablation, cathodic arc vaporization, or thermal evaporation. A method for forming metals may include metal plating, e.g., electroplating or chemical plating.

The term “forming” may also include a chemical reaction or fabrication of a chemical composition, where, for example, at least a portion of the layer, the material, or the region is formed by a transformation of one set of chemical substances into the chemical composition. “Forming” may, for example, include: changing the positions of electrons by breaking or forming chemical bonds between atoms of the set of chemical substances. The term “forming” may further include oxidation and reduction, complexation, precipitation, acid-base reaction, solid-state reaction, substitution, doping, addition and elimination, diffusion, or a photochemical reaction. “Forming” may, for example, change the chemical and physical properties of the set of chemical substances which chemically compose a portion of the layer, material, or region. Exemplary chemical properties or physical properties may include electrical conductivity, phase composition, or optical properties, etc. “Forming” may, e.g., include the application of a chemical reagent to an initial compound to change the chemical and physical properties of the initial compound.

The term “structuring” may refer to modifying the form of a structure (e.g., modifying the structure to achieve a desired shape or a desired pattern). To structure, e.g., a material, a portion of the material may be removed, e.g., via etching. To remove material from, for example a layer, material, or region, a mask (that provides a pattern) may be used, i.e., the mask provides a pattern for removing material (e.g., etching a structure to remove material of the structure) according to the pattern of the mask. Illustratively, the mask may prevent regions (which may be intended to remain) from being removed (e.g., by etching). Alternatively or additionally, to structure the layer, the material or the region of material may be disposed using a mask (the mask providing a pattern). The mask may provide a pattern for forming (e.g., disposing) material in accordance with the pattern of the mask.

In general, removing material may include a process such as etching of the material. The term “etching” may include various etching procedures, e.g., chemical etching (including, for example, wet etching or dry etching), physical etching, plasma etching, ion etching, etc. In etching a layer, a material, or a region, an etchant may be applied to the layer, the material, or the region. For example, the etchant may react with the layer, the material, or the region, forming a substance (or chemical compound) which may be easily removed, e.g., a volatile substance. Alternatively or additionally, the etchant may, for example, vaporize the layer, the material, or the region.

A mask may be a temporary mask, i.e., it may be removed after etching (e.g., the mask may be formed from a resin or a metal or another material such as a hard mask material such as silicon oxide, silicon nitride, or carbon, etc.) or the mask may be a permanent mask (e.g., a mask-blade), which may be used several times. A temporary mask may be formed, e.g., using a photomask.

According to various embodiments, a microelectromechanical device may be formed as part of, or may include, a semiconductor chip. For example, the semiconductor chip may include the microelectromechanical component (which may also be referred to as a microelectromechanical system). In other words, the microelectromechanical component may be implemented into (e.g., may be part of) a semiconductor chip, e.g., monolithically integrated. The semiconductor chip (which may also be referred to as a chip, die, or microchip) may be processed in semiconductor technologies, on a wafer, or in a wafer (or, e.g., a substrate or a carrier). The semiconductor chip may include one or more microelectromechanical systems (MEMS), which are formed during semiconductor technology processing or fabrication. The semiconductor carrier may be part of the semiconductor chip, e.g., the semiconductor carrier may be part of, or may form, the semiconductor body of the chip. Optionally, the microelectromechanical component may be part of, or may be electrically coupled to, an integrated circuit on the chip.

According to various embodiments, a semiconductor carrier (e.g., of a microelectromechanical device, e.g., the semiconductor carrier of a semiconductor chip) may be singulated from a wafer by removing material from a kerf region of the wafer (also referred to as dicing or cutting the wafer). For example, removing material from the kerf region of the wafer may be processed by scribing and breaking, cleavage, blade dicing, or mechanical sawing (e.g., using a dicing saw). In other words, the semiconductor carrier may be singulated by a wafer dicing process. After the wafer dicing process, the semiconductor carrier (or the finished microelectromechanical device) may be electrically contacted and encapsulated, e.g., by mold materials, into a chip carrier (which may also be referred to as a chip housing) which may then be suitable for use in electronic devices, such as gauges. For example, the semiconductor chip may be bonded to a chip carrier by wires. Furthermore, the semiconductor chip (which may be bonded to a chip carrier) may be mounted (e.g., soldered) onto a printed circuit board.

According to various embodiments, a semiconductor carrier (e.g., of a microelectromechanical device or the semiconductor carrier of a semiconductor chip) may include or may be made of (in other words, formed from) semiconductor materials of various types, including a group IV semiconductor (e.g., silicon or germanium), a compound semiconductor, e.g., a group III-V compound semiconductor (e.g., gallium arsenide), or other types, including group III semiconductors, group V semiconductors, or polymers, for example. In an embodiment, the semiconductor carrier may be made of silicon (doped or undoped). In an alternative embodiment, the semiconductor carrier may be a silicon on insulator (SOI) wafer. As an alternative, any other suitable semiconductor material may be used for the semiconductor carrier, for example, semiconductor compound material such as gallium phosphide (GaP), indium phosphide (InP), or any suitable ternary semiconductor compound material, such as indium gallium arsenide (InGaAs), or quaternary semiconductor compound material, such as aluminium gallium indium phosphide (AlInGaP).

According to various embodiments, a semiconductor carrier (e.g., of a microelectromechanical device or the semiconductor carrier of a semiconductor chip) may be covered with a passivation layer for protecting the semiconductor carrier from environmental influence, e.g., oxidation. The passivation layer may include a metal oxide, an oxide of the semiconductor carrier (which may also be referred to as a substrate or semiconductor body), e.g., silicon oxide, a nitride, e.g., silicon nitride, a polymer, e.g., benzocyclobutene (BCB) or polyimide (PI), a resin, a resist, or a dielectric material.

According to various embodiments, an electrically conductive material may include or may be formed from: a metal, a metal alloy, an intermetallic compound, a silicide (e.g., titanium silicide, molybdenum silicide, tantalum silicide, or tungsten silicide), a conductive polymer, a polycrystalline semiconductor, or a highly doped semiconductor, e.g., polycrystalline silicon (which may also be referred to as polysilicon), or a highly doped silicon. An electrically conductive material may be understood as material with moderate electrical conductivity, e.g., with an electrical conductivity (measured at room temperature and constant electric field direction) greater than about 10 S/m, e.g., greater than about 10² S/m, or with high electrical conductivity, e.g., greater than about 10⁴ S/m, e.g., greater than about 10⁶ S/m.

According to various embodiments, a metal may include or may be formed from one element of the following group of elements: aluminum, copper, nickel, magnesium, chromium, iron, zinc, tin, gold, silver, iridium, platinum, or titanium. Alternatively or additionally, a metal may include or may be formed from a metal alloy including one element or more than one element. For example, a metal alloy may include an intermetallic compound, e.g., an intermetallic compound of gold and aluminum, an intermetallic compound of copper and aluminum, an intermetallic compound of copper and zinc (brass) or an intermetallic compound of copper and tin (bronze).

According to various embodiments, an electrically insulating material, e.g., a dielectric material, may be understood as material with poor electrical conductivity, e.g., with an electrical conductivity (measured at room temperature and constant electric field direction) less than about 10⁻² S/m, e.g., less than about 10⁻⁵ S/m, or, e.g., less than about 10⁻⁷ S/m.

According to various embodiments, an insulating material may include a semiconductor oxide, a metal oxide, a ceramic, a semiconductor nitride, a metal nitride, a semiconductor carbide, a metal carbide, a glass, e.g., fluorosilicate glass (FSG), a dielectric polymer, a silicate, e.g., hafnium silicate or zirconium silicate, a transition metal oxide, e.g., hafnium dioxide or zirconium dioxide, an oxynitride, e.g., silicon oxynitride, or any other type of dielectric material. An insulating material may withstand an electric field without breaking down (in other words without experiencing failure of its insulating properties, e.g., without substantially changing its electrical conductivity).

According to various embodiments, a microelectromechanical component may be configured to at least one of: provide a force to actuate a diaphragm in response to an electrical signal transmitted to the electrically-conductive component and provide an electrical signal in response to an actuation of the diaphragm. In general, a microelectromechanical component may be configured to transfer mechanical energy into electrical energy and/or electrical energy into mechanical energy. In other words, a microelectromechanical component may function as a transducer that is configured to convert mechanical energy into electrical energy or vice versa. A microelectromechanical component may have a size in the range from about a few micrometers (μm) to about a few millimeters (mm), e.g., in the range from about a 10 μm to about 5 mm, e.g., in the range from about a 100 μm to about 2 mm, e.g., about 1 mm, or, alternatively, smaller than about 1 mm, e.g., smaller than 500 μm, e.g., smaller than 100 μm. A microelectromechanical component according to various embodiments may be processed in semiconductor technology.

A microelectromechanical component according to various embodiments may be used as a sensor (e.g., a micro-sensor) for sensing a mechanical signal and to generate an electrical signal which represents the mechanical signal. Alternatively, a microelectromechanical component may be used as an actuator for generating a mechanical signal based on the electrical signal. For example, the microelectromechanical component may be used as microphone or as a speaker (loudspeaker).

The microelectromechanical component may include a diaphragm. The diaphragm may be configured to actuate in response to a force. The force may be provided externally from the microelectromechanical component, i.e., the force may not originate from the microelectromechanical device. The force may be a mechanical interaction, i.e., a pressure-gradient, e.g., a mechanical wave (including acoustic waves or sound waves), pressure, such as gauge pressure. Additionally or alternatively, the force may be an electric field interaction, i.e., a Coulomb force or an electrostatic force, or may be a magnetic field interaction, e.g., magnetic force, such as Lorentz force, etc. An electrically-conductive component, e.g., an electrode or a sensor, may provide an electrical signal in response to the actuation of the diaphragm. The electrical signal may represent the force on the diaphragm or the actuation of the diaphragm (e.g., or the electrical signal may be proportional to the force).

Additionally or alternatively, the force to actuate the diaphragm may be provided by the microelectromechanical component, i.e., the force may originate from an element of the microelectromechanical component. For example, the force may be provided by an electrically-conductive component, e.g., an electrode that is part of the microelectromechanical component. The electrically-conductive component may provide a force to actuate the diaphragm in response to an electrical signal transmitted to the electrically-conductive component. The electrical signal may be transmitted by a circuit, e.g., a controller or a processor. The electrically-conductive component may exert a force on the diaphragm by an electric field interaction, a magnetic field interaction, or a combination thereof.

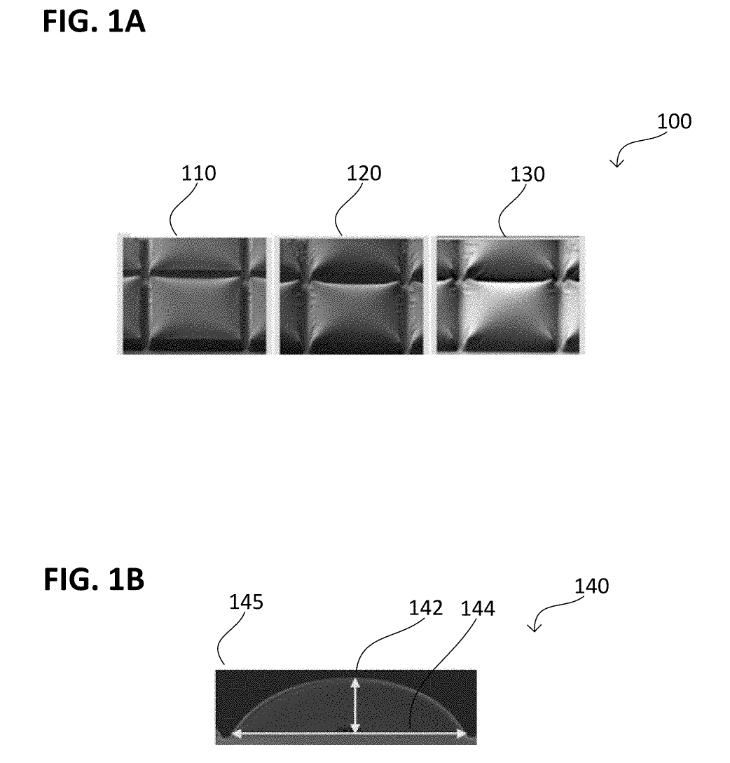

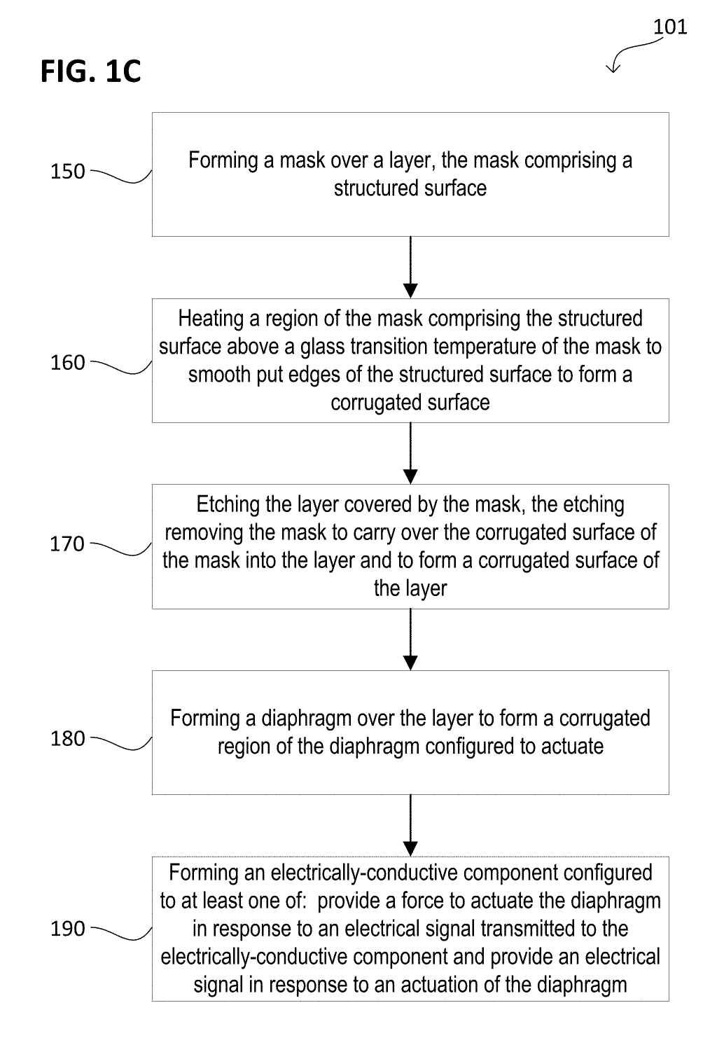

FIG. 1A-1B show rounding of photoresist, which may be used to manufacture a microelectromechanical component. A microelectromechanical component, such as a DBP microphone, may include two electrodes on either side of a membrane, or diaphragm. To manufacture such a component, processes such as a local oxidation of silicon (LOCOS) process may not be available, e.g., due to temperature budget constraints of the component and materials, to form a corrugated diaphragm. An exemplary process to achieve a corrugated diaphragm for a microelectromechanical component, for example, a component including two electrodes either side of the diaphragm, may include resist reflow techniques which may round, or smooth out, or form an undulating profile, in a polymer, e.g., photoresist, by heating.

FIG. 1A shows examples 100 of rounded polymers via a reflow technique, e.g., thermal reflow. The polymers may be or include a lacquer, resin, (photo)resist, etc. The polymers may be heated to at least the glass transition temperature of the polymer, which may be, for example, between 120° C. to 170° C.; for example, a diazonaphthoquinone-photoresist may have a glass transition temperature between 120° C. and 135° C., and may be heated to at least this temperature. The polymers may also be heated for a certain period of time, for example, a polymer may be heated to 140° C. for 2 minutes, e.g., a photoresist for lithographic processes. Example 110 shows an exemplary heating of a photoresist to 150° C. for about 1 minute to about 60 minutes. Example 120 shows an exemplary heating of a photoresist to 160° C. for 1 minute to about 60 minutes, and example 130 shows an exemplary heating of a photoresist to 170° C. for about 1 minute to about 60 minutes. As can be seen, different heating times and temperatures may cause the form of the photoresist to change, e.g., edges of the photoresist may be rounded.

Polymers may have a glass transition temperature (T_{g}) (as defined by viscosity, thermal expansion, heat capacity, shear modulus, or other properties, etc.). Increasing a temperature applied to a polymer increases a temperature of the polymer (or portions of the polymer, e.g., a thermal gradient in a structure including polymer), which may adjust, e.g., reduce, the viscosity of the polymer, thus causing the polymer to reflow and form a rounded surface, i.e., a profile or contour, of the polymer due to surface tension. The lateral reflow of the polymer may depend on a contact angle between the polymer and a solid surface (e.g., wettability of the solid surface).

FIG. 1B is a profile view 150 of photoresist structure 155 after heating, e.g., thermal reflow. Depending on temperature and time, a photoresist structure 155 may be formed with a designated width 154, e.g., in a range from about 1 μm to about 50 μm, e.g., about 17 μm, and height, e.g., in a range from about 1 μm to about 10 μm, e.g., about 4 μm.

Such thermal reflow techniques may be used to form a corrugated diaphragm, as discussed below. Corrugations, or undulations, in a diaphragm may increase the compliance of the diaphragm. Increased compliance may be used to form a diaphragm with a higher sensitivity. Corrugations with smooth (e.g., rounded, smoothed out, or undulating) transitions may avoid stress concentrations.

FIG. 1C depicts a method of manufacturing a microelectromechanical component 101, the method including: forming a mask over a layer, the mask comprising a structured surface 150; heating a region of the mask comprising the structured surface above a glass transition temperature of the mask to smooth out edges of the structured surface to form a corrugated surface 160; etching the layer covered by the mask, the etching removing the mask to carry over the corrugated surface of the mask into the layer and to form a corrugated surface of the layer 170; forming a diaphragm over the layer to form a corrugated region of the diaphragm configured to actuate 180; and forming an electrically-conductive component configured to at least one of: provide a force to actuate the diaphragm in response to an electrical signal transmitted to the electrically-conductive component and provide an electrical signal in response to an actuation of the diaphragm 190. Method 101 will be described in more detail in the following description of figures.

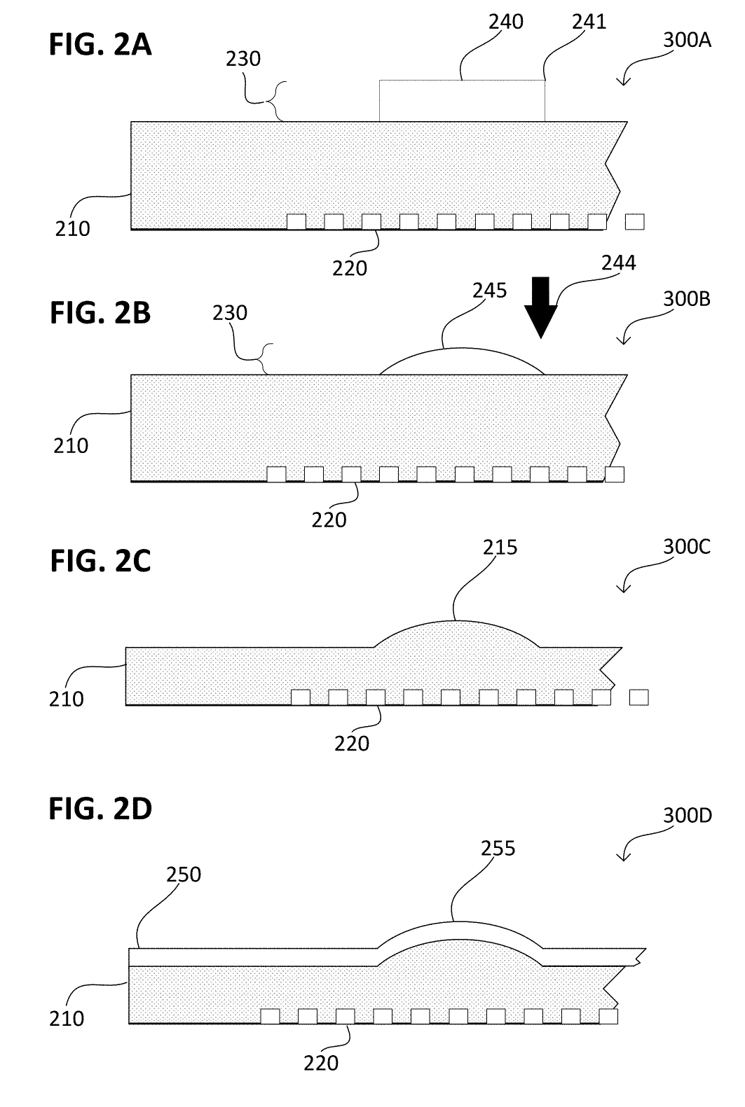

FIG. 2A-2D show, in a partial view of a cross-section, a method of manufacturing a microelectromechanical component and the components at various stages of manufacture according to an embodiment of the disclosure.

FIG. 2A shows the process 200A of forming a mask 230 over a layer 210, where the mask includes a structured (e.g., exposed) surface 240. FIG. 2A also depicts electrically-conductive component 220, e.g., an electrode.

As discussed above, mask 230 may be a polymer, e.g., a lacquer, a resin, a resist, or a photoresist. The mask 230 may be formed on layer 210, e.g., deposited. Layer 210 may be a substrate (a passive substrate material); e.g., formed of silicon, such as monocrystalline silicon, polycrystalline silicon, microcrystalline silicon, or nanocrystalline silicon; an oxide layer, such as an oxide of silicon, e.g., silicon dioxides or tetraethyl orthosilicate (TEOS). Electrically-conductive component 220, e.g., an electrode, may be formed in layer 210, e.g., electrically-conductive component 220 may be formed before layer 210 is deposited over the electrically-conductive component 220 or, alternatively, electrically-conductive component 220 may be formed in the layer 210, i.e., layer 210 may exemplarily be oriented in another manner and electrically-conductive component 220 may be formed over layer 210. Layer 210 may then be oriented in another manner for further processing. Alternatively, layer 210 may not require any reorientation to process multiple sides of the layer 210, thus mask 230 may be formed over layer 210 and electrically-conductive component 220 may be formed on the opposite side of layer 210 from mask 230 without any need to reorient layer 210.

Mask 230 may be altered (structured) to form structured surface 240 of the mask 230. Structuring the surface of mask 230 may vary the surface of the mask 230, e.g., changing a profile of the mask 230, patterning the mask 230, forming specific shapes in the mask 230. Structured surface 240 may have angular edges 241, e.g., due to an etching process. An angular edge may be an intersection of two surfaces, for example, a line formed from the intersection of two surfaces, such as an edge of a cube. A profile of structured surface 240 may, for example, be rectangular, trapezoidal, or be composed of a step-like profile. The overall shape of structured surface 240 may be a circle (or ring). Structured surface 240 of FIG. 2A may represent a cross-section of a portion of a ring.

Structured surface 240 may include any surface that has been altered into a desired or specified form from depositing or forming of mask 230 on layer 210. Structured surface 240 may include, for example, a protrusion, a recess, steps, or a geometric shape.

FIG. 2B shows process 200B of heating a region of the mask 230 including the structured surface 240 above a glass transition temperature of the mask 230 to smooth out edges 241 of the structured surface 240 to form a corrugated surface 245. Arrow 244 represents the transfer of thermal energy, i.e., heating.

A region of the mask 230 including the structured surface 240 may be locally heated or the entire arrangement depicted in process 200B may be heated. For example, structured surface 240 may be locally heated with focused thermal energy, e.g., laser radiation for locally induced heating, i.e., structured surface 240 may be selectively exposed to a heat source. Alternatively or additionally, layer 210 including electrically-conductive component 220 and mask 230 (and structured surface 240) may be simultaneously exposed to a heat source (e.g., a heat transfer).

Mask 230 may have a glass transition temperature and in process 200B, may be heated above the glass transition temperature of mask 230, i.e., of the material (or, e.g., materials) forming mask 230, or heated substantially to the glass transition temperature of mask 230. At the glass transition temperature, mask 230, including structured surface 240, may reflow, i.e., the viscosity of the material forming mask 230 may change, i.e., may be reduced thus causing mask 230 or structured surface 240 to flow. The final profile or shape of the structured surface 240 may be defined by a variety of factors, such as the material of the mask 230; the viscosity of the material forming the mask 230; the temperature of the structured surface 240 (mask 230); the temperature of the heat source (or the medium that is transferring thermal energy to the structured surface 240); the amount of time the structured surface 240 is exposed to the heat source; external forces acting on the structured surface 240, e.g., gravity; as well as internal forces of the structured surface 240, e.g., cohesive forces related to surface tension. The time and temperature the structured surface 240 is exposed to may each be predefined.

Based on at least the above-identified parameters, structured surface 240 may assume, e.g., transform, into another shape or profile. The resultant shape may have a reduced surface area and may smooth out, or round, any edges 241 of the structured surface 240. Structured surface 240 may form (e.g., may be transformed) into corrugated surface 245 of mask 230. Corrugated surface 245 may be a smoothed out, or rounded, version of structured surface 240 (e.g., a rounded variant or rendition of structured surface 240). Corrugated surface 245 may be ring-like in overall shape (FIG. 2B only depicts a portion of mask 230 and corrugated surface 245), having a rounded profile or cross-section.

FIG. 2C shows process 200C of etching the layer 210 covered by the mask 230, the etching removing the mask 230 to carry over the corrugated surface 245 of the mask 230 into the layer 210 and to form a corrugated surface 215 of the layer 210.

Etching layer 210 may partially or completely remove mask 230. Etching layer 210 may further carry over (i.e., reproduce or form in the layer) corrugated surface 245 of the mask 230, i.e., a surface of layer 210, after etching, may have a corrugated surface 215 where the mask 230 was etched. During process 200C a portion of layer 210 may be removed, for example, a sacrificial oxide may be removed from layer 210, i.e., the overall thickness of layer 210 may be reduced, while forming corrugated surface 215 in layer 210. Mask 230 and structured surface 240 thus act as a guide, affecting, or dictating in certain areas, the etching of the layer 210.

Etching the layer 210 may involve a selective etching process, i.e., the etchant may be selected to etch different materials at different rates, or may not etch a particular material. Additionally or alternatively, a dry-etching process may be used. Additionally or alternatively, the mask 230 and layer 210 may be etched at substantially similar rates, for example, the etch rate of layer 210 and mask 230 may be substantially 1:1.

FIG. 2D shows process 200D of forming a diaphragm 250 over the layer 210 to form a corrugated region 255 of the diaphragm 250, which is configured to actuate.

Diaphragm 250 may be formed over layer 210, including structured surface 215, i.e., diaphragm 250 may conform to the corrugated surface 215 of layer 210, e.g., diaphragm 250 may have a topography that corresponds to the topography of corrugated surface 215 and layer 210. Accordingly, diaphragm 250 may have a corrugated region 255 (a corrugated region in that the diaphragm 250 is three-dimensional and thus includes the corrugated, or undulating, region of the diaphragm 250).

The corrugated region 255 of the diaphragm 250 may have a round, wave-like profile, e.g., undulating or having smooth transitions. The corrugated region 255 may have an overall ring-like shape and may only be partially depicted in FIG. 2D, i.e., corrugated region 255 may include a circular structure with a rounded profile.

Diaphragm 250 may be composed of a crystalline material, e.g., a polycrystalline material or a nanocrystalline material. The diaphragm 250 may be composed of a conductive material, such as metal, or a semiconductive material, such as silicon, e.g., a polysilicon, nanocrystalline silicon, or an amorphous silicon.

Diaphragm 250 may be configured to actuate. Electrically-conductive component 220 may be configured to at least one of: provide a force to actuate the diaphragm 250 in response to an electrical signal transmitted to the electrically-conductive component 220 and provide an electrical signal in response to an actuation of the diaphragm 250.

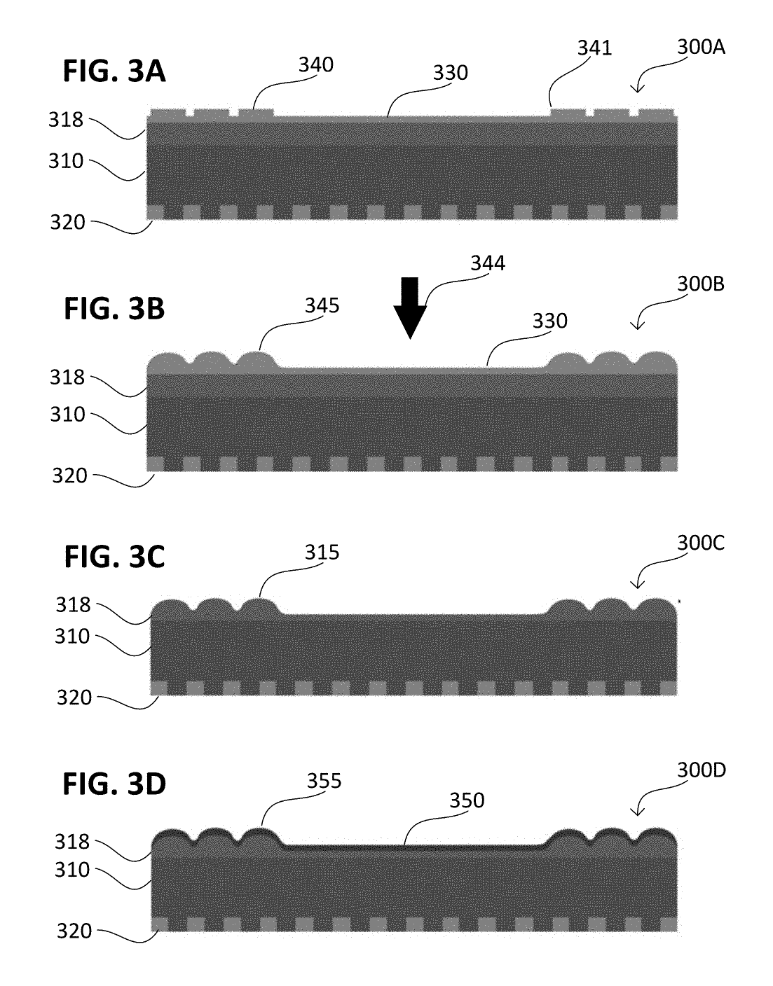

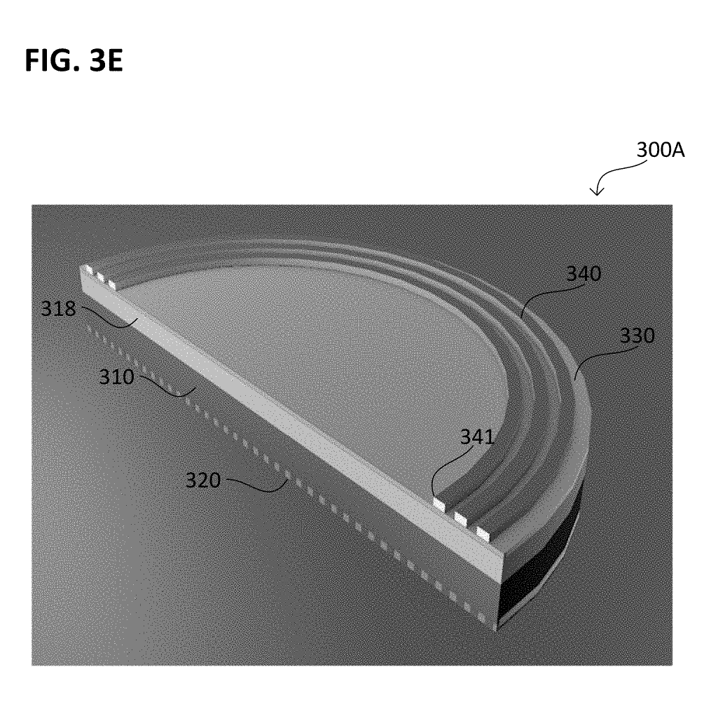

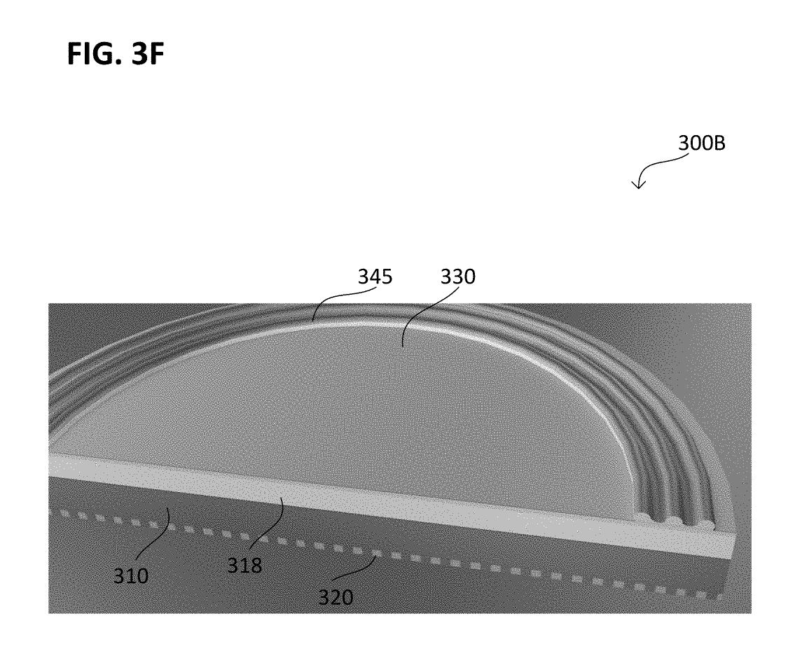

FIG. 3A-3D show, in cross-section, a method of manufacturing a microelectromechanical component and the components at various stages of manufacture according to an embodiment of the disclosure. FIG. 3A-3D may correspond to FIG. 2A-2D, and therefore, only differences between the figures may be discussed below.

FIG. 3A shows process 300A of forming a mask 330 over a layer 310, the mask 330 including a structured surface 340. FIG. 3A also depicts electrically conductive component 320, e.g., an electrode. FIG. 3A differs from FIG. 2A in that it shows a greater cross-section of the arrangement of process 300A.

Layer 310 may include a sacrificial portion 318, e.g., a sacrificial oxide layer. Mask 330 may completely cover at least one surface of layer 310 (as well as sacrificial portion 318).

Additionally, process 300A shows structured surface 340 of mask 330 having a plurality of structures having angular edges 341. Structured surface 340 may contain a plurality of circular structures, e.g., ring-like structures. The structures may protrude from the mask 330, or recesses may be formed in the mask 330. The plurality of structures, e.g., circular structures, included in structured surface 340 may be concentric.

FIG. 3B shows process 300B of heating a region of a mask 330 including the structured surface 340 above a glass transition temperature of the mask 330 to smooth out edges 341 of the structured surface 340 to form a corrugated surface 345. Arrow 344 represents the transfer of thermal energy, i.e., heating.

In process 300B, the arrangement may include a corrugated surface 345 including a plurality of circular, or ring-like, structures. The plurality of structures of corrugated surface 345 may be concentric. Transitions between the structures may be smooth and wave-like, i.e., undulating or corrugated. Angular edges 341 of the structured surface 340 may be rounded due to the heating; for example, heating above the glass transition temperature of a material of the mask 330 causes the viscosity of the material to vary and reflow into a structure with a rounded profile.

FIG. 3C shows process 300C of etching the layer 310 covered by the mask 330, the etching removing the mask 330 to carry over the corrugated surface 345 of the mask 330 into the layer 310 (e.g., sacrificial portion 318) and to form a corrugated surface 315 of the layer 310.

In process 300C, the corrugated surface 345 of mask 330 is carried over into the layer 310, i.e., the plurality of circular, or ring-like structures of corrugated surface 345 are also formed in corrugated surface 315 of the layer 310, for example. The plurality of structures of corrugated surface 315 may be concentric and have smooth or wave-like transitions between the structures, i.e., the corrugated surface 315 is undulating or corrugated.

FIG. 3D shows process 300D of forming a diaphragm 350 over the layer 310 (e.g., including sacrificial portion 318, corrugated surface 315) to form a corrugated region 355 of the diaphragm 350 configured to actuate.

In process 300D, the corrugated surface 315 of the layer 310 (or sacrificial portion 318) may serve as a mold for forming a diaphragm 350 over the layer 310 having a corrugated region 355. Forming diaphragm 350 over corrugated surface 315 imparts structure, e.g., the plurality of circular, ring-like structures of corrugated surface 315 are imparted (or reproduced or molded) into diaphragm 350, thus forming corrugated region 355. Corrugated region 355 may then have a plurality of circular, or ring-like structures having a smooth, wave-like transition between structures. The structures of the corrugated region 355 may be concentric. Corrugated region 355 may have any number of structures, e.g., 1 to 10 structures, or 6 structures (or corrugations).

FIG. 3E shows process 300A of forming a mask 330 over a layer 310, the mask 330 including a structured surface 340. FIG. 3A is a projection view of process 300A in cross-section.

A circular, or ring-like, structure of structured surface 340 (as well as mask 330) may be depicted in FIG. 3E. The structures may be spaced a distance from one another. This distance may vary or be uniform. The height and width of the structures may also vary or be uniform.

Similarly, FIG. 3F shows a projection view of a cross-section of process 300B of heating a region of the mask 330 including the structured surface 340 above a glass transition temperature of the mask 330 to smooth out edges of the structured surface 340 to form a corrugated surface 345.

In FIG. 3F, a circular, or ring-like, structure of corrugated surface 345 may be observed. Rounded transitions between structures of corrugated surface 345 may also be seen, as well as concentric structures.

Diaphragm 350 may be configured to actuate. Electrically-conductive component 320 may be configured to at least one of: provide a force to actuate the diaphragm 350 in response to an electrical signal transmitted to the electrically-conductive component 320 and provide an electrical signal in response to an actuation of the diaphragm 350.

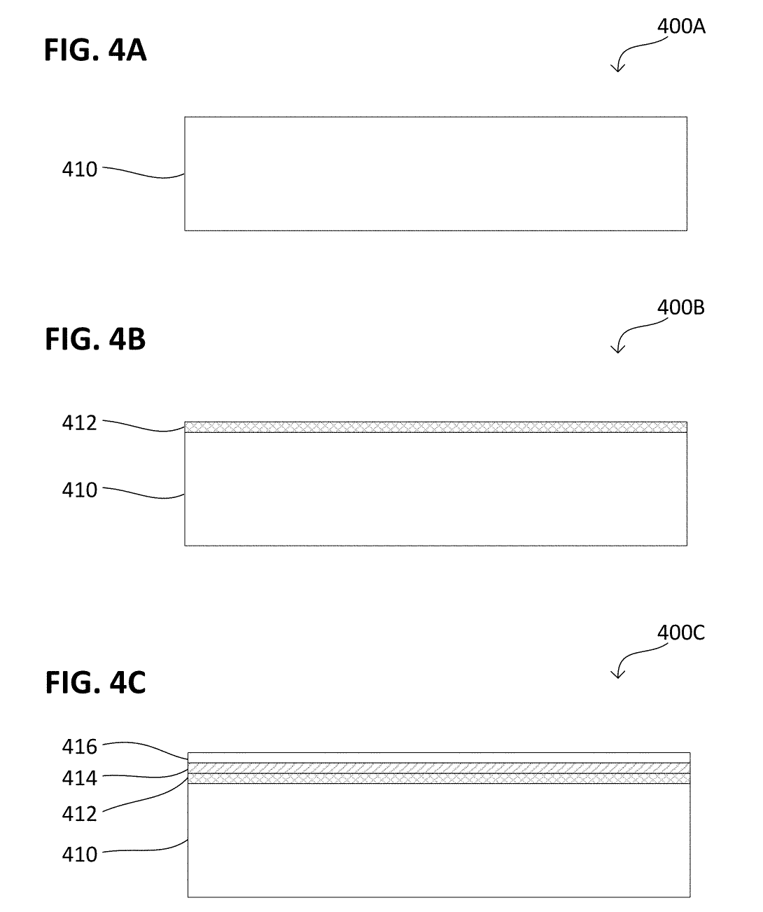

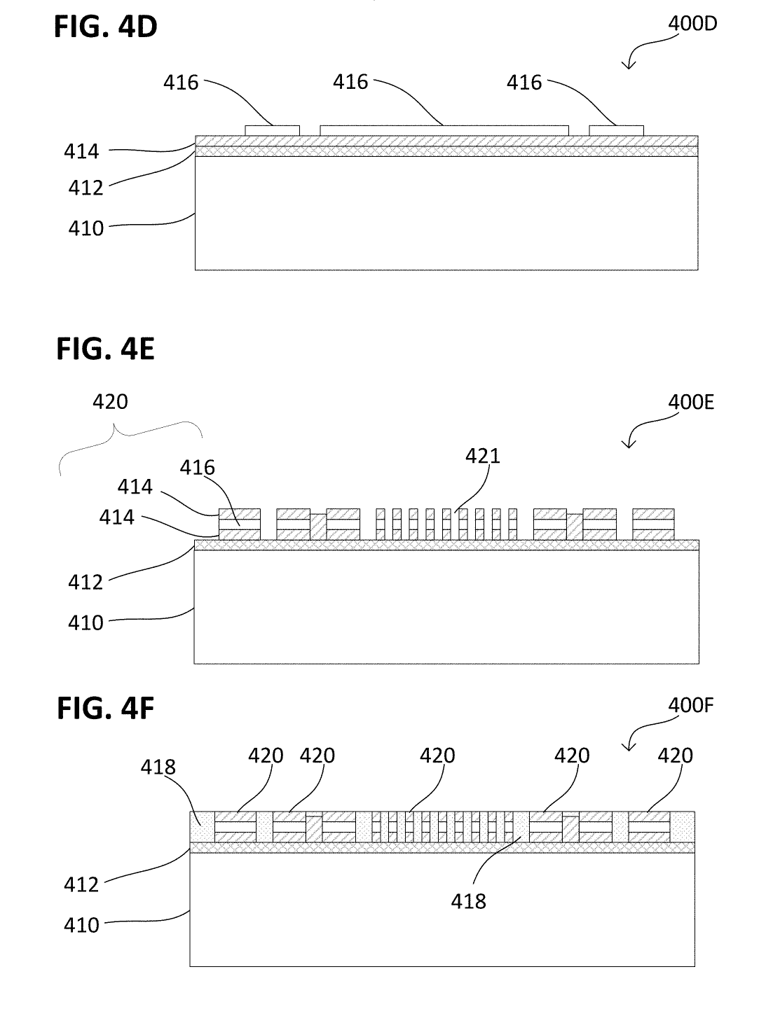

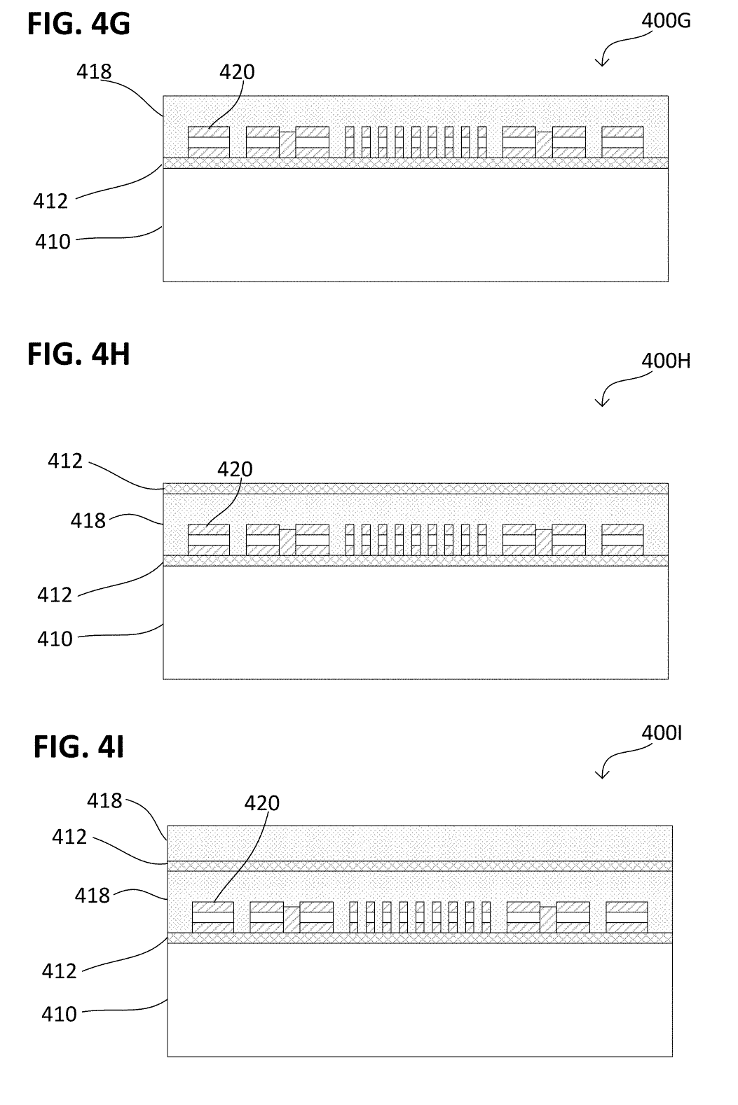

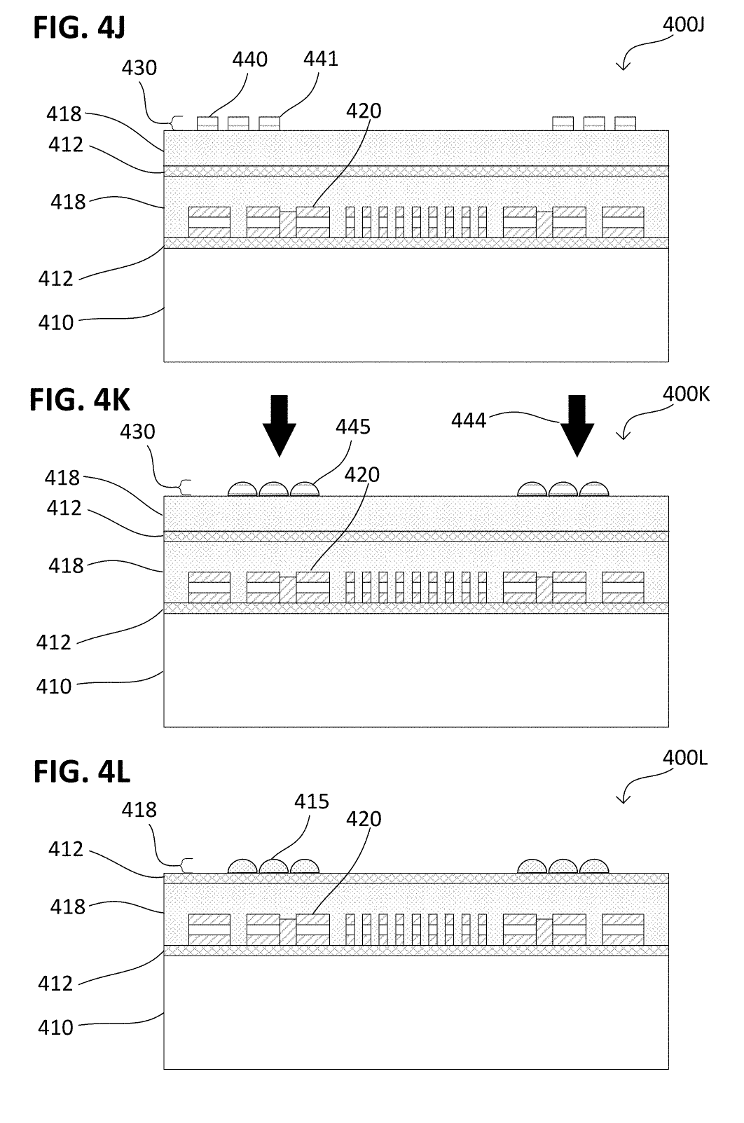

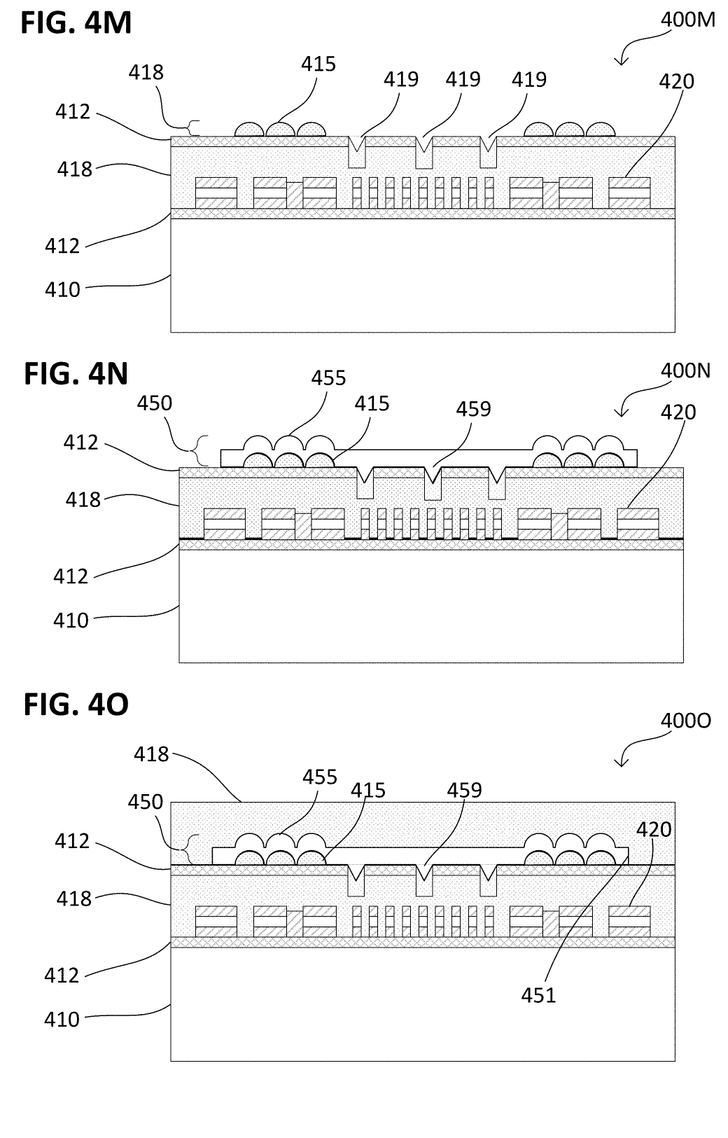

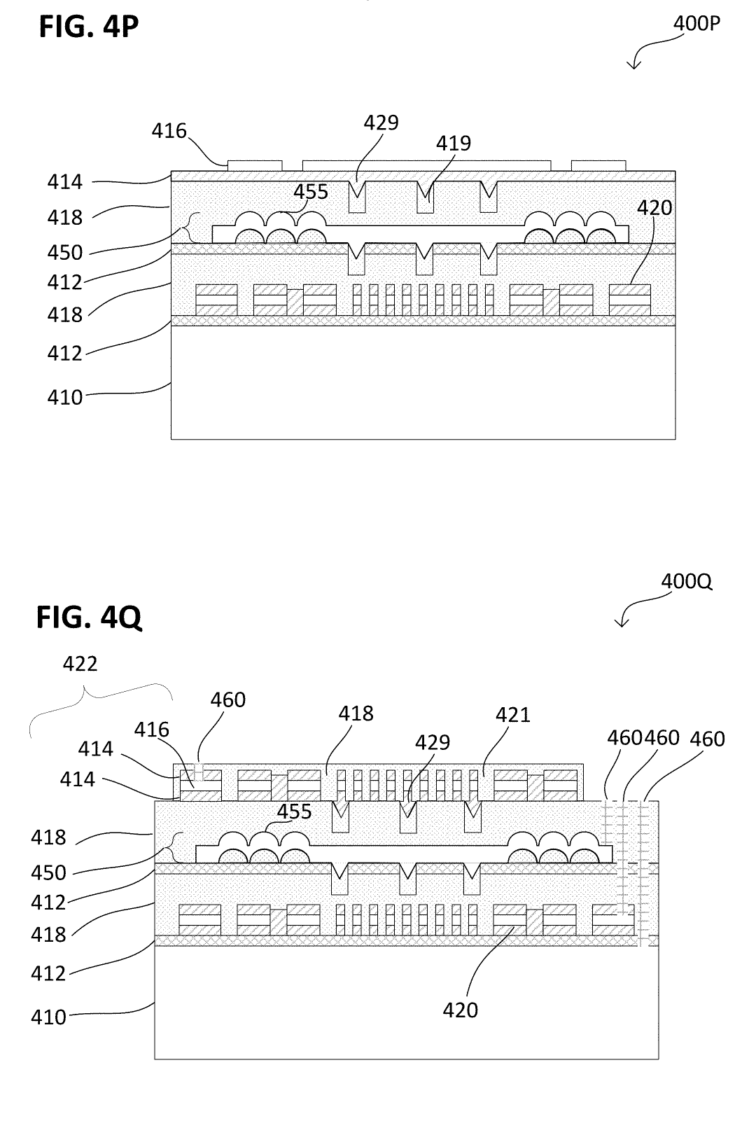

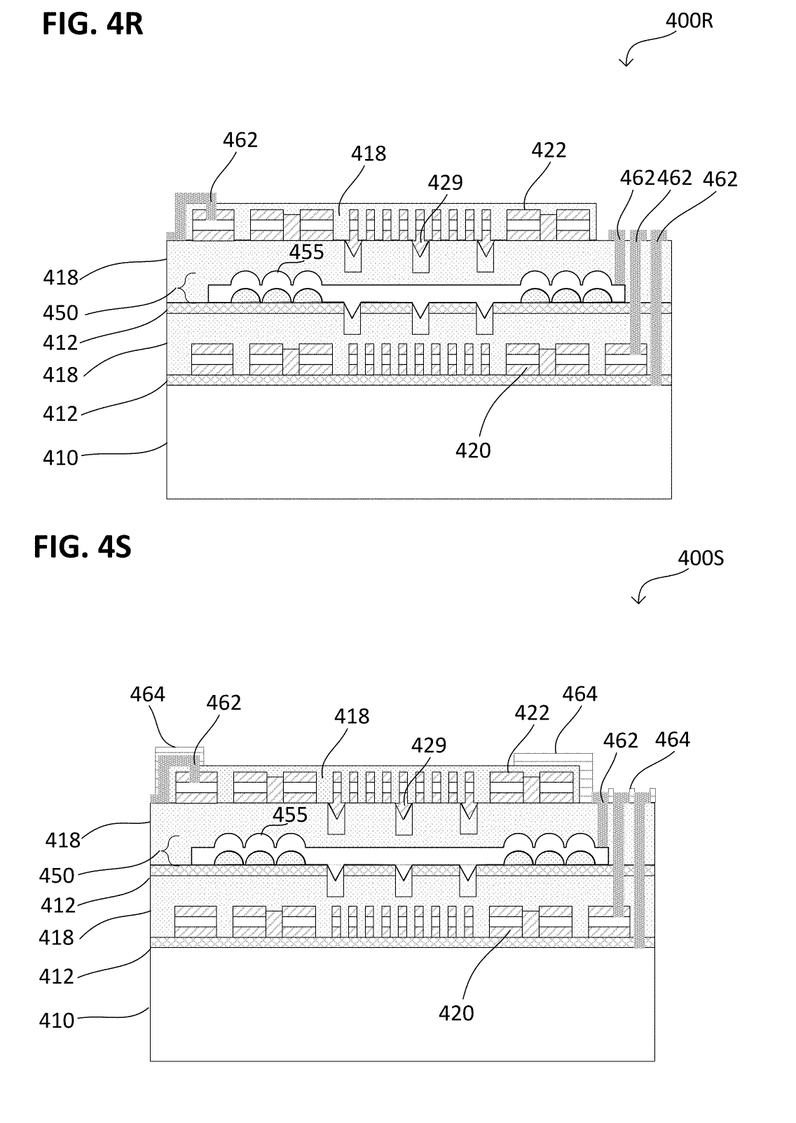

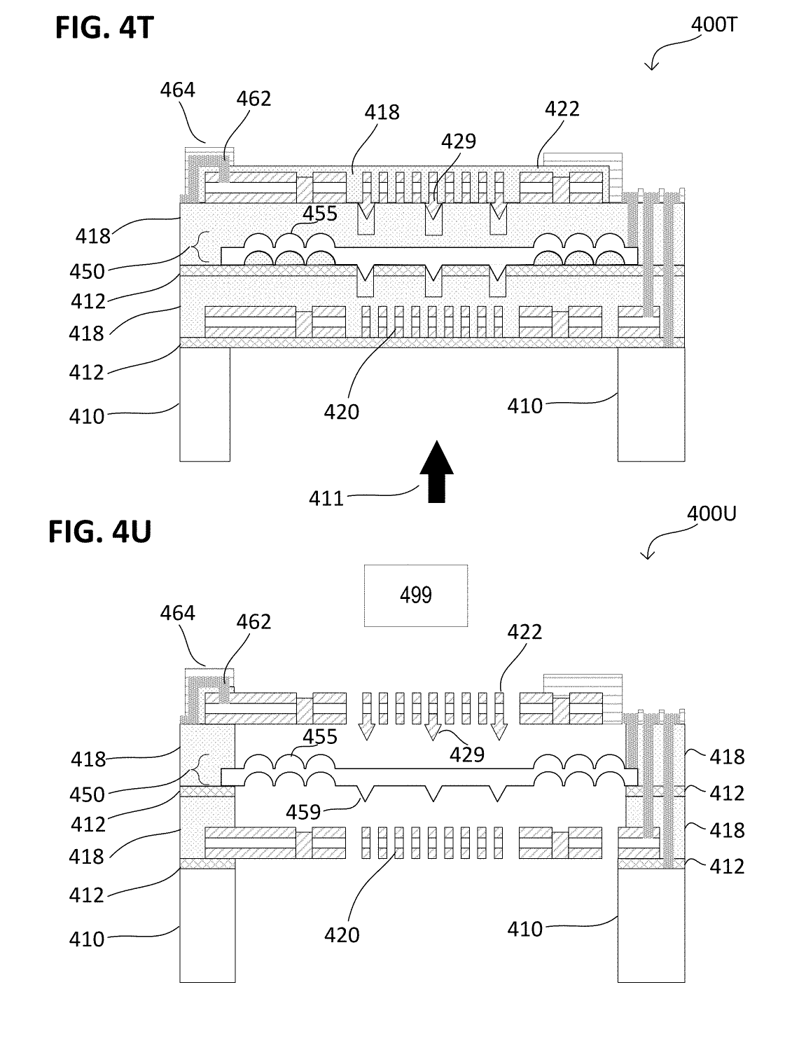

FIG. 4A-4U show, in cross-section, a method of manufacturing a microelectromechanical component and the components at various stages of manufacture according to an embodiment of the disclosure.

The method depicted in FIG. 4A-4U may be similar (or the same) to that of FIG. 2A-2D, as well as FIG. 3A-3F; however, FIG. 4A-4U may include additional (or optional) processes not depicted in other figures. Again, descriptions of similarly numbered elements may not be repeated here in entirety (e.g., layer 210, layer 310, layer 410).

FIG. 4A shows process 400A including layer 410. Layer 410 may be a substrate having a thickness. For example, the thickness of layer 410 may be based on various configurational requirements (or specifications) for the layer 410, for example, the thickness of layer 410 may range from about 50 μm to about 1 mm, e.g., about 725 μm. Layer 410 may be provided for further processing.

FIG. 4B shows process 400B of providing etch stop layer 412 on layer 410. Process 400B may be optional. Etch stop layer 412 may be an oxide, e.g., an oxide of silicon, such as tetraethyl orthosilicate (TEOS). Etch stop layer 412 may prevent an etchant from etching any materials under the layer 412.

FIG. 4C shows process 400C of providing a nitride layer 414 on layer 410 and providing a crystalline layer 416 on layer 410. Nitride layer 414 may be a silicon nitride, e.g., SiₓN_{y}, such as Si₃N₄. Crystalline layer 416 may, for example, by a polysilicon layer.

FIG. 4D shows process 400D of segmenting crystalline layer 416. Crystalline layer 416 may be etched to form multiple segments of crystalline layer 416. The etching process may be selected so as to be suitable for the material of crystalline layer 416.

FIG. 4E shows process 400E of providing an additional nitride layer 414 over crystalline layer 416 and etching nitride layers 414. Nitride layers 414 and crystalline layer 416 may together form an electrically-conductive component 420, e.g., an electrode or a backplate for a MEMS microphone. Etching nitride layers 414 may provide gaps 421, or backplate holes, in electrically-conductive component 420.

Gaps 421 allow a force (or incident pressure) to pass through electrically-conductive component 420 and impinge on other components (e.g., actuate or deflect diaphragm 450, discussed below). The number of gaps 421 in electrically-conductive component 420 may be selected to optimize a balance between compliance (e.g., suppleness or flexibility of the component 420) and capacitance of the electrically-conductive component. For example, a large number of gaps 421 may result in that the electrically-conductive component 420 is too compliant and may deflect in response to a force. Too much compliance of electrically-conductive component 420 may negatively affect performance of the microelectromechanical component. Similarly, a large number of gaps 421 reduces the area of a surface of electrically-conductive component 420, and may thus reduce the capacitance of electrically-conductive component 420, which may, again, negatively affect performance of the electrically-conductive component 420. Another consideration is that the number of gaps 421 may be related to the bandwidth of, e.g., a MEMS microphone, and may, for example over-damp a microphone if too few gaps 421 are provided.

A radius of gap 421 may be considered to affect the capacitance of electrically-conductive component 420, e.g., a smaller radius may utilize fringing electric fields to address capacitance loss.

FIG. 4F shows process 400F of forming an oxide layer 418 on electrically-conductive component 420. Oxide layer 418 may at least partially cover electrically-conductive component 420 (or completely cover all surfaces), i.e., gaps 421 may be filled in, as well as any other spaces in electrically-conductive component 420 with oxide layer 418.

Oxide layer 418 may be an oxide of silicon, such as silicon dioxide or TEOS. Oxide layer 418 may then be annealed, i.e., heating and allowing atom diffusion to reduce the presence of dislocations. Oxide layer 418 may be planarized, e.g., by chemical-mechanical polishing (CMP) to provide a surface for further processing.

FIG. 4G shows process 400G of forming additional oxide layer 418. As illustrated in FIG. 4G, additional oxide layer 418 may be a further layer of oxide deposited on the oxide layer 418 surrounding (or covering) electrically-conductive component 420 or oxide layer 418 may be deposited to surround electrically-conductive component 420 and fill beyond a thickness of electrically-conductive component 420. Oxide layer 418 may be annealed.

FIG. 4H shows process 400H of forming an additional etch stop layer 412. An additional etch stop layer over the electrically-conductive component 420 may be optional. An additional etch stop layer 412 may prevent any components underneath it from being etched during further processing, i.e., the additional etch stop layer 412 may not be reactive to a particular etchant. In addition, etch stop layer 412 may be a dielectric characterized by having a low leakage current and high thermal stability. The additional etch stop layer 412 may be an oxide, e.g., silicon oxynitride (SiOₓN_{y}), which may have an amorphous structure.

FIG. 4I shows process 400I of forming additional oxide layer 418 over an optional additional etch stop layer 412. Additional oxide layer 418 may be formed from an oxide of silicon, as discussed above. Additional oxide layer 418 of process 400I may provide a surface for further processing of additional components for the microelectromechanical component. Additional oxide layer 418 may, for example, be a sacrificial oxide layer, i.e., used as a mold for further processing.

FIG. 4J shows process 400J of forming a mask 430 over a layer 410, the mask 430 including a structured surface 440. Mask 430 may also be formed over electrically-conductive component 420.

Mask 430 may be formed on layer 410 and then structured, e.g., forming a recess in the mask 430 or forming protrusions on mask 430 (or a combination of both) to form structured surface 440. Alternatively or additionally, structured surface 440 of mask 430 may be formed in substantially a final profile (form) of the structured surface 440 on layer 410. Structured surface 440 may have angular edges 441. Structured surface 440 may be formed into a specified or desired shape, i.e., a topography or profile (e.g., a protrusion, a recess, steps, or a geometric shape). Similar to FIG. 3E, structured surface 440 may have an overall circular, or ring-like, structure, and may be composed of at least one, e.g., a plurality, of concentric structures. Mask 430 may be a polymer e.g., a lacquer, a resin, a resist, or a photoresist (similar to mask 230, mask 330) and layer 410 may be similar to that of layer 210 and layer 310.

FIG. 4K shows process 400K of heating (or baking) a region of the mask 430 including the structured surface 440 above a glass transition temperature of the mask 430 to smooth out edges 441 of the structured surface 440 to form a corrugated surface 445. Arrows 444 may represent transfer of thermal energy (heating).

As discussed above, a region of mask 430, e.g., structured surface 440, may be locally heated or the entire arrangement depicted in 400J may be heated. Mask 430 may have a glass transition temperature, and upon substantially reaching this temperature, the viscosity of mask 430 (and structured surface 440) may vary, e.g., decrease, and the material of mask 440, e.g., structured surface 440, may flow. A profile of structured surface 440, for example, may then be altered. Angular edges 441 may be rounded or smoothed out. Transitions between structures of the structured surface 440 may be smooth, thus forming a wave-like surface, i.e., an undulating or corrugated surface 445. Mask 430, or structured surface 440, may be heated for a predefined period of time and (substantially) a predefined temperature. As discussed above, various factors affect the degree of transformation (reformation, alteration, or reflow) of mask 430, for example, structured surface 440 in particular.

Corrugated surface 445 may be a smoothed-out, or rounded, version of structured surface 440. As discussed above, corrugated surface 445 may include a plurality of rounded, ring-like structures, which may be concentric.

FIG. 4L of process 400L of etching the layer 410 covered by the mask 430, the etching removing the mask 430 to carry over the corrugated surface 445 of the mask 430 into the layer 410 and to form a corrugated surface 415 of the layer 410. For processing, layer 410 may be considered to include any component or elements (e.g., oxide layers 418, etch stop layers 412, and electrically-conductive component 420) in or on layer 410 not involved (or intended to be directly affected) in immediate processing, for example, oxide layer 418 may be analogous to sacrificial portion 318, and may be considered part of layer 410, which may together function as a substrate or structure to facilitate processing (which may also, as discussed below, form a part (an integrated part) of the microelectromechanical component in later processing or the manufactured component).

As discussed above, etching layer 410 may partially or completely remove mask 430 and corrugated surface 445 may be formed in layer 410 (for example, oxide layer 418, which may be a sacrificial layer), i.e., etching mask 430 (including corrugated surface 445) may affect etching of layer 410 so that a corrugated surface 415 is formed (or reproduced or carried over into) in layer 410 (e.g., oxide layer 418). During process 400L the overall thickness of layer 410 may be reduced, e.g., further reaction with an etchant may be stopped by (additional or optional) etch stop layer 412, i.e., etch stop layer 412 may be a barrier preventing or hindering further etching below the layer 412. Etching may additionally or alternatively be stopped (halted, interrupted, or ended) by other conventional methods. The etching process 400L may be a selective etching process and may be a dry-etching process.

FIG. 4M shows process 400M of forming protrusion pattern 419 for diaphragm 450. Process 400M may be optional. Protrusion pattern 419 may be a cast, or a mold, for the formation of protrusions in further processing, i.e., protrusion pattern 419 is a cavity or void. Protrusion pattern 419 may be an arrangement of protrusions in a pattern or specified order. Individual cavities or voids may be cone-shaped, pyramid-shaped, or cylindrical.

Protrusion pattern 419 may be formed by removing a portion of oxide layer 418 (including optional etch stop layer 412). Oxide layer 418 (including etch stop layer 412, i.e., an etchant that may be reactive with etch stop layer 412 may be selected, which may be the same or different from an etchant selected to etch oxide layer 418; as an example, an etch rate for etch stop layer 412 and oxide layer 418 may be substantially different with the same etchant) may be etched or removed mechanically. This process may create a void or cavity larger than intended for an actual structural protrusion. Additional oxide material may then be deposited in the void (or along surfaces, such as sidewalls, of the void) to reduce the volume of the void, which may then form a cone-like or pyramid-like void (e.g., a cast).

FIG. 4N shows process 400N of forming a diaphragm 450 over the layer 410 to form a corrugated region 455 of the diaphragm 450, which is configured to actuate. Diaphragm 450 may further include protrusions 459, which may be configured to prevent static friction (stiction) during further processing (the protrusions may reduce a physical contact area of the diaphragm 450 with another component, e.g., electrically-conductive component 420). When forming diaphragm 450 (or membrane), material of diaphragm 450 may be formed in (e.g., fill) the cavities of protrusion pattern 419, thus forming the protrusions 459 on diaphragm 450.

Forming diaphragm 450 over layer 410 including corrugated surface 415 may conform a region of diaphragm 450 to the corrugated surface 415, and a corrugated region 455 may be produced in diaphragm 450. Corrugated region 455 may have at least one, or a plurality, of structures corresponding to corrugated surface 415. The structures of corrugated region 455 may be ring-like, or circular, and may be concentric. Corrugated region 455 may have a wave-like, or undulating region, with smooth transitions between structures, i.e., non-angular edges. Diaphragm 450 may be formed a predefined distance from electrically-conductive component 420.

In other words, corrugated surface 415 (and protrusion pattern 419) may form a mold (or cast) for the formation of diaphragm 450, including corrugated region 455. A thickness of diaphragm 450 may be substantially uniform, therefore, for example, the topography of corrugated surface 215 may be formed (reproduced) in the profile of diaphragm 450 (in particular, corrugated region 455) when being formed or deposited.

Similar to diaphragm 250 and 350, diaphragm 450 may be composed of a crystalline material, e.g., a polycrystalline material or a nanocrystalline material. The diaphragm 450 may be composed of a conductive material, such as metal, or a semiconductive material, such as silicon, e.g., a polysilicon, nanocrystalline silicon, or an amorphous silicon.

Diaphragm 450 may additionally (or optionally) be etched to define an outer boundary 451 of diaphragm 450. For example, if diaphragm 450 is circular, the diameter of diaphragm 450 may be reduced, or the outer boundary 451 may be etched to form a specified shape or pattern, which may be a geometric shape.

FIG. 4O shows process 400O of forming additional oxide layer 418 over diaphragm 450. Additional oxide layer 418 may at least partially (or completely) cover diaphragm 450. As discussed above, oxide layer 418 may be formed from an oxide of silicon, e.g., tetraethyl orthosilicate. Additional oxide layer 418 may be annealed, and may be planarized, e.g., by a CMP process, to provide a surface for further processing.

FIG. 4P shows process 400P of forming a further protrusion pattern 419 for further protrusions 429 for further electrically-conductive component 422. Additional oxide layer 418 may be structured to form a further protrusion pattern 419, i.e., a pattern of voids or cavities. This process may create a void or cavity larger than intended for an actual structural protrusion. Additional oxide material may then be deposited in the void (or along surfaces, such as sidewalls, of the void) to reduce the volume of the void, which may then form a cone-like or pyramid-like void (e.g., a cast).

A further nitride layer 414 may then be deposited over diaphragm 450, e.g., over additional oxide layer 418 including further protrusion pattern 419. Further nitride layer 414 may be deposited in further protrusion pattern (which may be optional), for example, nitride material may be deposited in (or fill) the voids or cavities of further protrusion pattern 419, thus forming a further nitride layer 414 having further protrusions 429. Further protrusions 429 may reduce a contact area of further electrically-conductive component 422 in further processing with diaphragm 450. Further protrusions 429 may thus reduce static friction (stiction) between further electrically-conductive component 422 and other components. As discussed above, further nitride layer 414 may be formed from, e.g., silicon nitride, SiₓN_{y}.

A further crystalline layer 416 may be formed on further nitride layer 414. As discussed above, further crystalline layer 416 may be formed, e.g., from polysilicon. Further crystalline layer 416 be segmented, e.g., etched to form multiple segments of further crystalline layer 416.

FIG. 4Q shows process 400Q of forming additional further nitride layer 414 on further crystalline layer 416, thus forming further electrically-conductive component 422; forming additional oxide layer 418; and forming access points 460 to various components, such as layer 410, electrically-conductive component 420, diaphragm 450, and further electrically-conductive component 422.

Forming further electrically-conductive component 422 may also include etching further nitride layers 414 and further crystalline layer 416 to form further gaps 421 (as discussed above). Further electrically-conductive component 422 may include the protrusions 429.

An additional further oxide layer 418 may be formed over further electrically-conductive component 422. This oxide layer 418 may at least partially (or completely) cover, e.g., surround all surfaces of, further electrically-conductive component 422.

Access points 460 may then be formed, for example, by etching through oxide layer(s) 418 and nitride layer(s) 414 to various electrically-conductive layers of the microelectromechanical component, e.g., electrically-conductive component 420, further electrically-conductive component 422, and diaphragm 450, as well as layer 410.

FIG. 4R shows process 400R of forming contacts 462 in access points 460, e.g, forming a metallic or conductive contact, such as metallization. A negative mask or lift-off process may be used to deposit a metal on the arrangement in process 400R. For example, titanium, platinum, or gold may be formed, or deposited. The metallic material may contact the various electrically-conductive layers of the microelectromechanical component, e.g., electrically-conductive component 420, further electrically-conductive component 422, and diaphragm 450, as well as layer 410, by at least partially filling access points 460. Contacts 462 (e.g., contact pads) may be used to externally electrically contact the microelectromechanical component.

FIG. 4S shows process 400S of forming a passivation layer 464 at least partially on the microelectromechanical component, e.g., to passivate any exposed metallization (excluding portions of contacts 462). For example, a layer of silicon nitride may be deposited on further electrically-conductive component 422 and metallic contacts 462. The layer of silicon nitride may then be etched to expose contacts 462 and provide an opening (as seen here in cross-section) above further electrically-conductive component 422. The opening may be in the form of a geometric shape, e.g., a circle.

FIG. 4T shows process 400T of forming a recess 411 in layer 410. Forming the recess 411 may include grinding a surface of layer 410, e.g., a backside, or exposed surface of layer 410, i.e., a surface of layer 410 not proximate to electrically-conductive component 420. Grinding may be a process of physically removing material from layer 410, such as abrasion (or abrasive cutting). Additionally or alternatively, recess 411 may be formed by deep reactive-ion etching, e.g., via the Bosch process (pulsed or time-multiplexed etching). The Bosch process, for example, may include repetitive (iterative) steps of isotropic etching and deposition of a passivation layer (including sidewalls of the targeted etch area), which may achieve a step-wise substantially vertical etch to a desired (predefined) depth, e.g., to electrically-conductive component 420 or to a region proximate to electrically-conductive component 420.

FIG. 4U shows process and microelectromechanical component 400U of releasing electrically-conductive component 420, diaphragm 450, and further electrically-conductive component 422, from any surrounding and intervening layers, e.g., oxide layers 418 and etch stop layers 412. The components may be released by an etch process to remove, for example, portions of oxide layers 418 and etch stop layers 412. As can be exemplarily seen in FIG. 4U, oxide layers 418 and etch stop layers 412 may not be completely released and may form structural supports for the electrically-conductive component 420, diaphragm 450, and further electrically-conductive component 422, while an intervening material between active regions of the components may be completely removed. Thus, the microelectromechanical component may be formed.

Microelectromechanical component 400U may be a MEMS device, such as a transducer, or a microphone, or a dual-backplate (DBP) microphone. Diaphragm 450 may be configured to actuate. Electrically-conductive component 420 may be configured to at least one of: provide a force to actuate the diaphragm 450 in response to an electrical signal transmitted to the electrically-conductive component and provide an electrical signal in response to an actuation of the diaphragm 450.

For example, in an aspect of the disclosure, the microelectromechanical component may be a MEMS microphone and a force, e.g., a pressure gradient, such as a mechanical wave (including a sound wave, as well as non-auditory mechanical waves or impulses), external fluid pressure (external from the component, including, for example, gauge pressure) may cause diaphragm 450 to actuate, or move, in relation to the magnitude of the force impinging the diaphragm 450. Diaphragm 450 may have, for example, a capacitive relationship with electrically-conductive component 420 and/or further electrically-conductive component 422. Actuation of diaphragm 450 may then change an electrically capacitive relationship, e.g., the magnitude of the capacitance, between, for example, diaphragm 450 and electrically-conductive component 420, thus an electrical signal may be produced in electrically-conductive component 420, for example, this change in capacitance may occur and be detected by circuitry connected to the electrically-conductive component 420 and/or diaphragm 450 (such circuitry 499, which may, for example, be external to the microelectromechanical component or may be integrated with the microelectromechanical component and may be electrically contacted to contacts 462).

Diaphragm 450 may be biased by an external voltage, i.e., provided with a voltage, e.g., contacted at contact 462 for the diaphragm 450, such as in a condenser microphone, or diaphragm 450 may, for example, maintain an embedded static electrical charge, such as in an electret microphone.

Alternatively or additionally, electrically-conductive component 420 (as well as further electrically-conductive component 422) may provide a force to actuate the diaphragm 450 in response to an electrical signal transmitted to the electrically-conductive component 420. For example, the electrical signal may provide a voltage to electrically-conductive component 420 (and/or further electrically-conductive component 422), which may provide an electric field interaction or magnetic field interaction on diaphragm 450 (e.g., exert an electric force) causing diaphragm 450 to actuate. This actuation may produce a mechanical wave, e.g., a sound wave, thus allowing microelectromechanical component 400U to operate as a speaker.

A DBP arrangement for a MEMS microphone may be advantageous, e.g., electrically-conductive component 420 and further electrically-conductive component 422 may be electrodes and form dual backplates for diaphragm 450. As the MEMS microphone may have two backplates, sensitivity of the component may be increased due to the presence of two electrodes, or even more accurate measurement (or detection) by providing a second electrode. Sensitivity of the component may also be increased as the dual backplates allow for higher bias voltages, which may exert similar (or cancelling) electrostatic forces on, e.g., diaphragm 450, which may reduce effects of pull-in (diaphragm attraction to an electrode due to electrostatic forces, which may lead to, e.g., diaphragm collapse).

Additionally, a diaphragm 450 having a corrugated region 455 may increase bandwidth and sensitivity of the component, e.g., due to increased compliance of the diaphragm 450. The rounded, or smoothed out, transitions of corrugated region 455 avoid concentrations of internal stress, e.g., in an angular edge of diaphragm corrugation, when diaphragm 450 is actuated, which may, e.g., lead to component failure or inaccurate measurement.

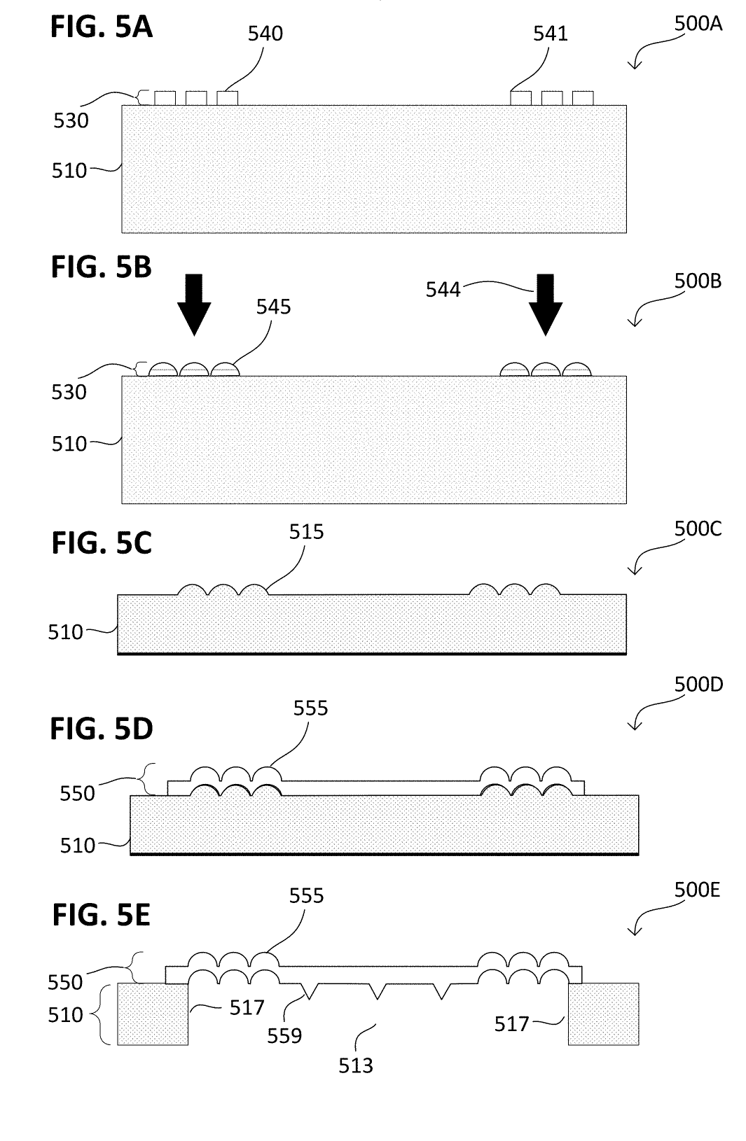

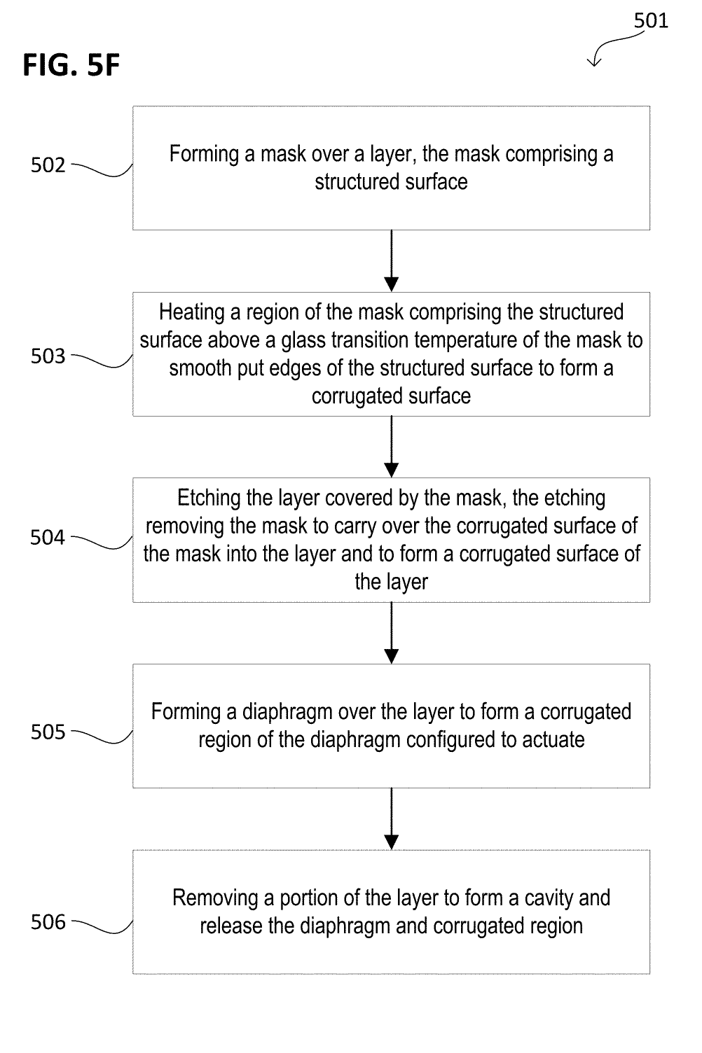

FIG. 5A-5E show, in cross-section, an aspect of the disclosure of a method of manufacturing a microelectromechanical component and the components at various stages of manufacture according to an embodiment of the disclosure.

FIG. 5A shows process 500A of forming a mask 530 over a layer 510, the mask including a structured surface 540. Layer 510 may be a substrate, which may, for example, be formed from: silicon, such as monocrystalline silicon, polycrystalline silicon, or nanocrystalline silicon; or an oxide, such as an oxide of silicon, e.g., TEOS. Mask 530 may be a polymer, e.g., a lacquer, a resin, a resist, or a photoresist.

Mask 530 may include structured surface 540. Structuring the surface of mask 530 may vary the surface of the mask 530, e.g., changing a profile of the mask 530, patterning the mask 530, forming a shape or shapes in the mask 530. Structured surface 540 may have angular edges 541, e.g., due to an etching process. A profile of structured surface 540 may, for example, be rectangular, trapezoidal, or be composed of a step-like profile. Structured surface 540 may include any surface that has been altered into a desired or specified form from depositing or forming of mask 530 on layer 510. Structured surface 540 may include, for example, a protrusion, a recess, steps, or a geometric shape. The overall shape of structured surface 540 may be a circle (or ring). Structured surface 540 may also include a plurality of rings, which may be concentric.

FIG. 5B shows process 500B of heating a region of the mask 530 including the structured surface 240 above a glass transition temperature of the mask 530 to smooth out edges 541 of the structured surface 540 to form a corrugated surface 545. Arrow 544 represents the transfer of thermal energy, i.e., heating.

A region of the mask 530 including the structured surface 540 may be locally heated or the entire arrangement depicted in process 500B may be heated. For example, structured surface 540 may be locally heated with focused thermal energy, e.g., laser radiation for locally induced heating, i.e., structured surface 540 may be selectively exposed to a heat source. Alternatively or additionally, layer 510 including electrically-conductive component 520 and mask 530 (and structured surface 540) may be simultaneously exposed (e.g., a heat transfer) to a heat source.

Mask 530 may have a glass transition temperature and in process 500B, may be heated above the glass transition temperature of mask 530, i.e., of the material (or, e.g., materials) forming mask 530, or heated substantially to the glass transition temperature of mask 530. At the glass transition temperature, mask 530, including structured surface 540, may reflow, i.e., the viscosity of the material forming mask 530 may change, i.e., may be reduced, thus causing mask 530 or structured surface 540 to flow. Structured surface 540 (as well as mask 530) may be heated for a predefined time period. Structured surface 540 (as well as mask 530) may be heated to substantially a predefined temperature, e.g., taking into account heating device precision or tolerancing. The final profile or shape of the structured surface 540 may be defined by a variety of factors, such as the material of the mask 530; the temperature of the structured surface 540 (mask 530); the temperature of a heat source (or the medium that is transferring thermal energy to the structured surface 540); the amount of time the structured surface 540 is exposed to the heat source; the viscosity of the material forming the mask 530, which may vary, e.g., due to a temperature of the material; external forces acting on the structured surface 540, e.g., gravity; as well as internal forces of the structured surface 540, e.g., cohesive forces related to surface tension.

Based on at least the above-identified parameters, structured surface 540 may assume, e.g., transform, into another shape or profile. The resultant shape may have a reduced surface area and may smooth out, or round, any edges 541 or the structured surface 540. Structured surface 540 may form (e.g., may be transformed) into corrugated surface 545 of mask 530. Corrugated surface 545 may be a smoothed out, or rounded, version of structured surface 540 (e.g., a rounded variant or version of structured surface 540). Corrugated surface 545 may be ring-like in overall shape, having a rounded profile or cross-section. Corrugated surface 545 may include a plurality of rounded, ring-like structures forming a plurality of rounded protrusions, e.g., an undulating or wave-like surface.

FIG. 5C shows process 500C of etching the layer 510 covered by the mask 530, the etching removing the mask 530 to carry over the corrugated surface 545 of the mask 530 into the layer 510 and to form a corrugated surface 515 of the layer 510.

Etching layer 510 may partially or completely remove mask 530. Etching layer 510 may further carry over (i.e., reproduce or form in the layer) corrugated surface 545 of the mask 530, i.e., a surface of layer 510, after etching, may have a corrugated surface 515 where the mask 530 was etched. During process 500C a portion of layer 510 may be removed, for example, a sacrificial oxide may be removed from layer 510, i.e., the overall thickness of layer 510 may be reduced, while forming corrugated surface 515 in layer 510. Mask 530 and structured surface 540 thus acts as a guide, affecting, or dictating in certain areas, the etching of the layer 510.

Etching the layer 510 may involve a selective etching process, i.e., the etchant may be selected to etch different materials at different rates, or may not etch a particular material. Additionally or alternatively, a dry-etching process may be used. Alternatively, the mask 530 and layer 510 may be etched at substantially similar rates.

FIG. 5D shows process 500D of forming a diaphragm 550 over the layer 510 to form a corrugated region 555 of the diaphragm 550. Layer 510 including corrugated surface 515 may be a mold for forming diaphragm 550, i.e., layer 510 including corrugated surface 515 may be a pattern for the fabrication of diaphragm 550. Corrugated surface 515 may then be imparted in diaphragm 550 when formed over layer 510 including corrugated surface 515. Diaphragm 550 may be deposited over layer 510 and corrugated surface 515 with a substantially similar thickness, so that underlying features, e.g., protrusions and recesses, may be reproduced in diaphragm 550, for example, the formation of corrugated region 555.

FIG. 5E shows process 500E of removing a portion of the layer 510 to form a cavity 513 and release the diaphragm 550 and corrugated region 555. Process 500E may further include removing the portion of the layer 510 to form a mechanical support 517 for the diaphragm 550. Diaphragm 550 may also include protrusions 559, as discussed above.

Mechanical support 517 may provide a structure that anchors, or is a base structure or frame for, diaphragm 550. Mechanical support 517 may be formed from layer 510, i.e., layer 510 may be both a mold, and after release of diaphragm 550, may also be formed as a mechanical support 517 for diaphragm 550. Diaphragm 550 may be suspended from mechanical support 517.

Release of diaphragm 550 may involve removing material, e.g., layer 510, in physical contact with an active region of diaphragm 550, whether the material is over or under diaphragm 550, so that diaphragm 550 may actuate, e.g., in response to a force.

FIG. 5F depicts a method of manufacturing a microelectromechanical component 501, the method comprising: forming a mask over a layer, the mask comprising a structured surface 502; heating a region of the mask comprising the structured surface above a glass transition temperature of the mask to smooth out edges of the structured surface to form a corrugated surface 503; etching the layer covered by the mask, the etching removing the mask to carry over the corrugated surface of the mask into the layer and to form a corrugated surface of the layer 504; forming a diaphragm over the layer to form a corrugated region of the diaphragm 505; removing a portion of the layer to form a cavity to allow the corrugated region of the diaphragm to actuate 506. Method 501 corresponds to the process described in detail above, e.g., FIG. 5A-5E and related text.

In an Example 1 of an aspect of the disclosure, a method of manufacturing a microelectromechanical component, the method including: forming a mask over a layer, the mask comprising a structured surface; heating a region of the mask comprising the structured surface above a glass transition temperature of the mask to smooth out edges of the structured surface to form a corrugated surface; etching the layer covered by the mask, the etching removing the mask to carry over the corrugated surface of the mask into the layer and to form a corrugated surface of the layer; forming a diaphragm over the layer to form a corrugated region of the diaphragm configured to actuate; and forming an electrically-conductive component configured to at least one of: provide a force to actuate the diaphragm in response to an electrical signal transmitted to the electrically-conductive component and provide an electrical signal in response to an actuation of the diaphragm.

Example 2 may include the method of Example 1, wherein the diaphragm is actuated by a mechanical interaction, an electric field interaction, a magnetic field interaction, or any combination thereof.

Example 3 may include the method of Example 2, wherein the electrically-conductive component exerts the electric field interaction, the magnetic field interaction, or any combination thereof

Example 4 may include the method of Examples 1-3, further including: forming a further electrically-conductive component configured to at least one of: provide a further force to actuate the diaphragm in response to an electrical signal transmitted to the electrically conductive component and provide a further electrical signal in response to an actuation of the diaphragm.

Example 5 may include the method of Example 4, wherein the further electrically-conductive component exerts a further electric field interaction, a further magnetic field interaction, or any combination thereof.

Example 6 may include the method of Example 4, wherein the further electrically-conductive component is formed over the diaphragm.

Example 7 may include the method of Example 4, wherein the further electrically-conductive component is a further electrode.

Example 8 may include the method of Example 4, wherein forming the further electrically-conductive component further comprises: forming further protrusions extending toward the diaphragm, the protrusions configured to prevent static friction.

Example 9 may include the method of Examples 1-8, further comprising: forming an etch-stop layer that is non-reactive with an etchant used to etch the layer.

Example 10 may include the method of Example 9, wherein the etch-stop layer is formed over the electrically-conductive element.

Example 11 may include the method of Examples 9 and 10, further comprising: forming a further etch-stop layer that is non-reactive with the etchant.

Example 12 may include the method of Example 11, wherein the further etch-stop layer is formed over the diaphragm.

Example 13 may include the method of Example 1, wherein forming the structured surface of the mask comprises a lithographic process.

Example 14 may include the method of Example 13, wherein the lithographic process is a photolithographic process.

Example 15 may include the method of Example 13, wherein the lithographic process is a grey-scale lithographic process.

Example 16 may include the method of Example 1, wherein the mask comprises photoresist.

Example 17 may include the method of Example 1, wherein the structured surface comprises at least one recess.

Example 18 may include the method of Example 17, wherein the at least one recess comprises a plurality of concentric circular recesses.

Example 19 may include the method of Example 1, wherein the structured surface comprises at least one protrusion.

Example 20 may include the method of Example 19, wherein the structured surface comprises at least one circular protrusion.

Example 21 may include the method of Example 20, wherein the structured surface comprises a plurality of concentric circular protrusions.

Example 22 may include the method of Example 1, wherein heating the region of the mask above the glass transition temperature of the mask reflows the region of the mask.

Example 23 may include the method of Example 1, wherein heating the region of the mask above the glass transition temperature of the mask rounds the region of the mask according to a surface tension of the mask.

Example 24 may include the method of Example 1, wherein heating the region of the mask above the glass transition temperature of the mask changes a viscosity of the mask.

Example 25 may include the method of Example 1, wherein the region of the mask is heated to substantially a predefined temperature above the glass transition temperature of the mask.

Example 26 may include the method of Example 1, wherein the region of the mask is heated above the glass transition temperature of the mask for a predefined period of time.

Example 27 may include the method of Example 1, wherein etching the layer comprises: an anisotropic dry-etching process.

Example 28 may include the method of Example 1, wherein an etch rate of the mask and an etch rate of the layer are substantially similar.

Example 29 may include the method of Example 1, wherein an etch rate of the mask and an etch rate of the layer are substantially dissimilar.

Example 30 may include the method of Example 1, wherein the diaphragm comprises a crystalline material.

Example 31 may include the method of Example 34, wherein the crystalline material is silicon.

Example 32 may include the method of Example 1, wherein the diaphragm comprises a polycrystalline material.

Example 33 may include the method of Example 32, wherein the polycrystalline material is polysilicon.

Example 34 may include the method of Example 1, wherein the diaphragm comprises a nanocrystalline material.

Example 35 may include the method of Example 34, wherein the nanocrystalline material is nanocrystalline silicon.

Example 36 may include the method of Example 1, wherein the diaphragm comprises an amorphous silicon.

Example 37 may include the method of Example 1, wherein the diaphragm comprises a metal.

Example 38 may include the method of Example 1, wherein forming the diaphragm further comprises: forming protrusions extending toward the electrically-conductive component, the protrusions configured to prevent static friction.

Example 39 may include the method of Example 1, wherein the corrugated region comprises a circular structure with a rounded profile.

Example 40 may include the method of Example 1, wherein the corrugated region comprises a plurality of concentric circular structures having a rounded transition between the plurality of concentric circular structures.

Example 41 may include the method of Example 1, wherein the diaphragm is formed over the electrically-conductive component.

Example 42 may include the method of Example 1, wherein the diaphragm is formed a predefined distance from the electrically-conductive component.

Example 43 may include the method of Example 1, wherein the force to actuate the diaphragm is exerted by a mechanical interaction, an electric field interaction, a magnetic field interaction, or any combination thereof.

Example 44 may include the method of Example 1, wherein the electrically-conductive component is formed in the layer.

Example 45 may include the method of Example 1, wherein the electrically-conductive component is an electrode.

Example 46 may include the method of Example 1, wherein the electrically-conductive component provides the force to activate the diaphragm by an electric field interaction, a magnetic field interaction, or any combination thereof.

In an Example 47 of an aspect of the disclosure, a method of manufacturing a microelectromechanical component, the method including: forming a mask over a layer, the mask comprising a structured surface; heating a region of the mask comprising the structured surface above a glass transition temperature of the mask to smooth out edges of the structured surface to form a corrugated surface; etching the layer covered by the mask, the etching removing the mask to carry over the corrugated surface of the mask into the layer and to form a corrugated surface of the layer; forming a diaphragm over the layer to form a corrugated region of the diaphragm; and removing a portion of the layer to form a cavity and release the diaphragm and corrugated region.

Example 48 may include the method of Example 47, further including: removing the portion of the layer to form a mechanical support for the diaphragm.

Example 49 may include the method of Example 47, further including: forming an electrically-conductive component configured to at least one of: provide a force to actuate the diaphragm in response to an electrical signal transmitted to the electrically-conductive component and provide an electrical signal in response to an actuation of the diaphragm.

Example 50 may include the method of Examples 47-49, further including: forming a further electrically-conductive component configured to at least one of: provide a further force to actuate the diaphragm in response to an electrical signal transmitted to the electrically conductive component and provide a further electrical signal in response to an actuation of the diaphragm.

In an Example 51 of an aspect of the disclosure, a microelectromechanical component may include: an electrically-conductive component; a diaphragm disposed over the electrically-conductive component, the diaphragm comprising a corrugated region configured to actuate; and a further electrically-conductive component disposed over the diaphragm; wherein the electrically-conductive component is configured to at least one of: provide a force to actuate the diaphragm in response to an electrical signal transmitted to the electrically conductive component and provide an electrical signal in response to an actuation of the diaphragm; and wherein the further electrically-conductive component is configured to at least one of: provide a further force to actuate the diaphragm in response to a further electrical signal transmitted to the further electrically-conductive component and provide a further electrical signal in response to an actuation of the diaphragm.

Example 52 may include the method of Example 51, wherein the diaphragm further comprises: protrusions extending toward the electrically-conductive component, the protrusions configured to maintain a minimal distance between the diaphragm and the electrically-conductive component.

Example 53 may include the method of Example 51, wherein the further electrically-conductive component further comprises: further protrusions extending toward the diaphragm, the protrusions configured to maintain a minimal distance between the diaphragm and the further electrically-conductive component.

Example 54 may include the method of Example 51, wherein the electrically-conductive component is an electrode.

Example 55 may include the method of Example 51, wherein the further electrically-conductive component is a further electrode.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims, and all changes within the meaning and range of equivalency of the claims are therefore intended to be embraced.

What is claimed is:

1. A method of manufacturing a microelectromechanical component, the method comprising:
forming a mask over a layer, the mask comprising a structured surface;
heating a region of the mask comprising the structured surface above a glass transition temperature of the mask to smooth out edges of the structured surface to form a corrugated surface;
etching the layer covered by the mask, the etching removing the mask to carry over the corrugated surface of the mask into the layer and to form a corrugated surface of the layer;
forming a diaphragm over the layer to form a corrugated region of the diaphragm configured to actuate; and
forming an electrically-conductive component configured to at least one of:
provide a force to actuate the diaphragm in response to an electrical signal transmitted to the electrically-conductive component and
provide an electrical signal in response to an actuation of the diaphragm.

2. The method of claim 1,
wherein the diaphragm is actuated by a mechanical interaction, an electric field interaction, a magnetic field interaction, or any combination thereof.

3. The method of claim 2,
wherein the electrically-conductive component exerts the electric field interaction, the magnetic field interaction, or any combination thereof.

4. The method of claim 1, further comprising:
forming a further electrically-conductive component configured to at least one of:
provide a further force to actuate the diaphragm in response to an electrical signal transmitted to the electrically-conductive component and
provide a further electrical signal in response to an actuation of the diaphragm.

5. The method of claim 4,
wherein the further electrically-conductive component exerts a further electric field interaction, a further magnetic field interaction, or any combination thereof.

6. The method of claim 4,
wherein the further electrically-conductive component is formed over the diaphragm.

7. The method of claim 1,
wherein the mask comprises photoresist.

8. The method of claim 1,
wherein the structured surface comprises at least one protrusion.

9. The method of claim 8,
wherein the structured surface comprises at least one circular protrusion.

10. The method of claim 1,
wherein heating the region of the mask above the glass transition temperature of the mask changes a viscosity of the mask.

11. The method of claim 1,
wherein the region of the mask is heated to substantially a predefined temperature above the glass transition temperature of the mask.

12. The method of claim 1,
wherein the region of the mask is heated above the glass transition temperature of the mask for a predefined period of time.

13. The method of claim 1,
wherein the diaphragm comprises a crystalline material, wherein the crystalline material is silicon.

14. The method of claim 1,
wherein the diaphragm comprises a metal.

15. The method of claim 1,
wherein the corrugated region comprises a circular structure with a rounded profile.

16. The method of claim 1,
wherein the corrugated region comprises a plurality of concentric circular structures having a rounded transition between the plurality of concentric circular structures.

17. The method of claim 1,
wherein the force to actuate the diaphragm is exerted by a mechanical interaction, an electric field interaction, a magnetic field interaction, or any combination thereof.

18. A method of manufacturing a microelectromechanical component, the method comprising:
forming a mask over a layer, the mask comprising a structured surface;
heating a region of the mask comprising the structured surface above a glass transition temperature of the mask to smooth out edges of the structured surface to form a corrugated surface;
etching the layer covered by the mask, the etching removing the mask to carry over the corrugated surface of the mask into the layer and to form a corrugated surface of the layer;
forming a diaphragm over the layer to form a corrugated region of the diaphragm; and
removing a portion of the layer to form a cavity and release the diaphragm and corrugated region.

19. The method of claim 18, further comprising:
removing the portion of the layer to form a mechanical support for the diaphragm.

20. A microelectromechanical component comprising:
an electrically-conductive component;
a diaphragm disposed over the electrically-conductive component, the diaphragm comprising a corrugated region configured to actuate; and
a further electrically-conductive component disposed over the diaphragm;
wherein the electrically-conductive component is configured to at least one of:
provide a force to actuate the diaphragm in response to an electrical signal transmitted to the electrically-conductive component and
provide an electrical signal in response to an actuation of the diaphragm; and
wherein the further electrically-conductive component is configured to at least one of:
provide a further force to actuate the diaphragm in response to a further electrical signal transmitted to the further electrically-conductive component and
provide a further electrical signal in response to an actuation of the diaphragm.
